(19) United States
(12) Patent Application Publication
(10) Pub. No.: US 2026/0276762 A1
(43) Pub. Date: Sep. 17, 2026

(54) MRI RF COIL COMPRISING A MULTI-ELEMENT CHANNEL STRUCTURE AND METHOD FOR USING THE SAME

(71) Applicant: Quality Electrodynamics, LLC, Mayfield Village, OH (US)

(72) Inventors: Xiaoyu Yang, Indiana, PA (US); Thomas Eastlake, Cleveland, OH (US); Tsinghua Zheng, Chesterland, OH (US); Matthew Finnerty, University Heights, OH (US)

(21) Appl. No.: 19/558,762

(22) Filed: Mar. 6, 2026

Related U.S. Application Data
(60) Provisional application No. 63/770,409, filed on Mar. 12, 2025.

(51) Int. Cl. G01R 33/36; G01R 33/34

(52) U.S. Cl. CPC G01R 33/3628; G01R 33/34069; G01R 33/365

(57) ABSTRACT

The present disclosure provides a magnetic resonance imaging (MRI) radio frequency (RF) coil with a multi-element channel structure, as well as a system comprising the MRI RF coil and a method for using the multi-element channel structure. A first coil element and a second coil element border each other. A first matching circuit is electrically coupled from a first channel port to the first coil element and to the second coil element, and a second matching circuit is electrically coupled from the second channel port to the first coil element and to the second coil element. Further, each of the first and second matching circuits is configured to match the first and second coil elements simultaneously.

### REFERENCE TO RELATED APPLICATION

This application claims the benefit of U.S. Provisional Application No. 63/770,409, filed on Mar. 12, 2025, the contents of which are incorporated herein by reference in their entirety.

### BACKGROUND

Magnetic resonance imaging (MRI) involves the transmission and reception of radio frequency (RF) energy. RF energy may be transmitted by an RF coil to create a B₁ field that rotates net magnetization. Further, resulting magnetic resonance (MR) signals may be received by an RF coil to detect precessing transverse magnetization. Thus, RF coils may be transmit (Tx) coils, receive (Rx) coils, or transmit/receive (Tx/Rx) coils.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a diagram of some embodiments of a magnetic resonance imaging (MRI) radio frequency (RF) coil comprising a multi-element channel structure.

FIGS. 2A and 2B illustrate diagrams of some embodiments of current patterns for a first channel and a second channel in the MRI RF coil of FIG. 1.

FIG. 3 illustrates a table of some embodiments of current patterns for a first channel and a second channel in the MRI RF coil of FIG. 1.

FIG. 4 illustrates a diagram of some alternative embodiments of the MRI RF coil of FIG. 1 in which feed points are varied.

FIG. 5 illustrates a diagram of some embodiments of the MRI RF coil of FIG. 1 in which matching circuits comprise phase shifters.

FIGS. 6A-6D illustrate diagrams of some embodiments of different types of “π” and “T” phase shifters for use as the phase shifters of FIG. 5.

FIG. 7 illustrates a diagram of some embodiments of the MRI RF coil of FIG. 5 in which the phase shifters are shown as “π” phase shifters as in FIGS. 6A and 6B.

FIG. 8 illustrates a graph of some embodiments of results for an S-parameter simulation using the MRI RF coil of FIG. 7.

FIG. 9 illustrates a diagram of some alternative embodiments of the MRI RF coil of FIG. 7 in which feed points are varied.

FIGS. 10A and 10B illustrate diagrams of some embodiments of different types of lattice baluns for use as the phase shifters of FIG. 5.

FIG. 11 illustrates a diagram of some embodiments of the MRI RF coil of FIG. 5 in which the phase shifters are shown as lattice baluns as in FIGS. 10A and 10B.

FIG. 12 illustrates a diagram of some alternative embodiments of the MRI RF coil of FIG. 11 in which feed points are varied.

FIG. 13 illustrates a diagram of some alternative embodiments of the MRI RF coil of FIG. 1 in which a loop coil element is replaced with a saddle coil element.

FIGS. 14A and 14B illustrate diagrams of some alternative embodiments of the MRI RF coil of FIG. 13 in which feed points are varied.

FIG. 15 illustrates a diagram of some alternative embodiments of the MRI RF coil of FIG. 13 in which the saddle coil element has a different configuration.

FIG. 16 illustrates a diagram of some alternative embodiments of the MRI RF coil of FIG. 13 in which relative positioning between coil elements is varied.

FIG. 17 illustrates a diagram of some alternative embodiments of the MRI RF coil of FIG. 1 in which loop coil elements are replaced with saddle coil elements.

FIG. 18 illustrates a diagram of some alternative embodiments of the MRI RF coil of FIG. 17 in which feed points are varied.

FIG. 19 illustrates a diagram of some alternative embodiments of the MRI RF coil of FIG. 17 in which the saddle coil elements have a different configuration.

FIG. 20 illustrates a diagram of some alternative embodiments of the MRI RF coil of FIG. 17 in which relative positioning between coil elements is varied.

FIG. 21 illustrates a diagram of some alternative embodiments of the MRI RF coil of FIG. 1 in which the multi-element channel structure has an additional element per channel.

FIG. 22 illustrates a table of some embodiments of phase shifts while matching coil elements to channels in the MRI RF coil of FIG. 21.

FIG. 23 illustrates a diagram of some embodiments of the MRI RF coil of FIG. 21 in which matching circuits comprise phase shifters.

FIG. 24 illustrates a diagram of some embodiments of an MRI RF coil comprising multiple coil groups that share a single balun.

FIG. 25 illustrates a diagram of some embodiments of an MRI RF coil comprising multiple coil groups with different numbers of coil elements.

FIG. 26 illustrates a diagram of some embodiments of an MRI RF coil comprising multiple coil groups spread amongst two rows.

FIG. 27 illustrates a table of some embodiments of isolations between channels of a four-channel parallel transmit (pTx) MRI RF coil with a dual-element channel structure.

FIGS. 28A and 28B illustrate various diagrams of some embodiments of an MRI system comprising an MRI RF coil with a multi-element channel structure.

FIG. 29 illustrates a diagram of some alternative embodiments of the MRI system of FIGS. 28A and 28B in which the MRI system comprises a T/R switch.

FIG. 30 illustrates a block diagram of some embodiments of a method of performing MRI using an MRI RF coil comprising a multi-element channel structure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purposes of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to one or more other elements or features as illustrated in the figures. The spatially relative terms are intended to encompass different orientations of the device in use or operation in addition to the orientation depicted in the figures. The apparatus may be otherwise oriented (e.g., rotated 90 degrees or at other orientations), and the spatially relative descriptors used herein may likewise be interpreted accordingly.

A phased array coil is an approach to building a multiple-channel magnetic resonance (MR) receiver (Rx) coil. It provides signal penetration at depth comparable to that of a large coil, while maintaining the high signal performance of a small coil near the surface. Coupling between adjacent coil elements may be minimized by overlapping them. Coupling between non-adjacent elements may be minimized by using low-input-impedance preamplifiers.

Besides the overlap approach, a shared-capacitor approach may be used to achieve good isolation between two coil channels. This method works for both adjacent and non-adjacent elements. However, a disadvantage of the shared-capacitor approach is that it produces a dark area directly beneath the shared-capacitor coil path when that path extends perpendicular to a direction of the B₀ field. This occurs because the B₁ field generated by the shared coil path is oriented along the B₀ field in the region underneath it, and only the component of the B₁ field that is perpendicular to the B₀ field contributes to signal detection. As a result, signal sensitivity is low in the region underneath the shared coil path.

Coil elements of a phased array coil may be loop-shaped or saddle-shaped. The aforementioned decoupling methods can be applied between any combination of these element types: two loops, two saddles, or a loop and a saddle. Accordingly, both loops and saddles may be used to construct a phased array coil with suitable decoupling.

Although the phased array coil achieves a combined signal-to-noise ratio (SNR) at depth comparable to that of a large loop, it has an intrinsic disadvantage compared to a single large loop of the same overall size. To illustrate this disadvantage, consider two configurations: 1) a two-channel phased array coil comprising two overlapping loops; and 2) a single-channel loop coil whose outline matches the overall outline of the two-channel phased array. Note that the crosses at the overlapping area of the two-channel phased array coil are small compared to the overall coil size and may therefore be ignored.

Both the two-channel phased array coil and the single-channel loop coil capture MR signal at a similar level at depth. This is because the currents in the two loops of the phased array coil flow in opposite directions through the overlap region, effectively canceling. The overlap region therefore contributes negligibly to the net B₁ field at depth, and the effective current path of the phased array coil resembles that of the single-channel loop coil. However, although the traces in the overlap region contribute negligibly to signal, they still contribute noise.

The two-channel phased array coil generates coil-only noise from all of its traces, including the traces in the overlap region, whereas the single-channel loop coil generates coil-only noise from only its perimeter traces. Because the single-channel loop coil produces significantly less coil-only noise for a similar signal level, it achieves a better SNR at depth. The same conclusion is also applicable to a two-channel phased array coil that uses the shared-capacitor decoupling approach in place of the overlap decoupling approach.

If the total coil noise is not dominated by sample noise (e.g., coil elements are small or operating at 1.5 T and below), the multi-element disadvantage can be significant. Further, this disadvantage becomes more significant if the number of channels increases while the overall size of the coil remains unchanged. Therefore, a multi-channel phased array coil as described may have lower SNR than a single-channel loop coil with the same outline at deep areas, due to additional coil noise from non-circumference coil traces.

One way to boost SNR is quadrature reception, which employs at least two receiver channels whose B₁ fields are approximately orthogonal to each other. However, a single-channel loop coil, comprising only one loop, cannot alone support quadrature reception, whereas a two-channel phased array coil inherently supports multiple channels and thus enables quadrature or quadrature-like reception. This makes it possible to further enhance SNR through quadrature or quadrature-like reception at the same deep-tissue region.

The present disclosure introduces a magnetic resonance imaging (MRI) radio frequency (RF) coil with a multi-element channel structure, as well as a system comprising the MRI RF coil and a method for using the multi-element channel structure. As detailed below, this structure reduces noise from inner conductor traces while enabling quadrature-like reception at deep tissue regions, thereby enhancing overall coil SNR. Additionally, the multi-element channel structure is suitable for both transmission and reception applications.

In some embodiments, the MRI RF coil includes at least one coil channel group in which the number of channels equals or exceeds the number of coil elements within that group. Each channel is simultaneously matched to at least two coil elements within the same group, and each coil element is concurrently coupled to at least two different channels via matching circuits. This structure enables enhanced channel isolation, reduced coil noise, and improved SNR without sacrificing spatial coverage or parallel imaging performance.

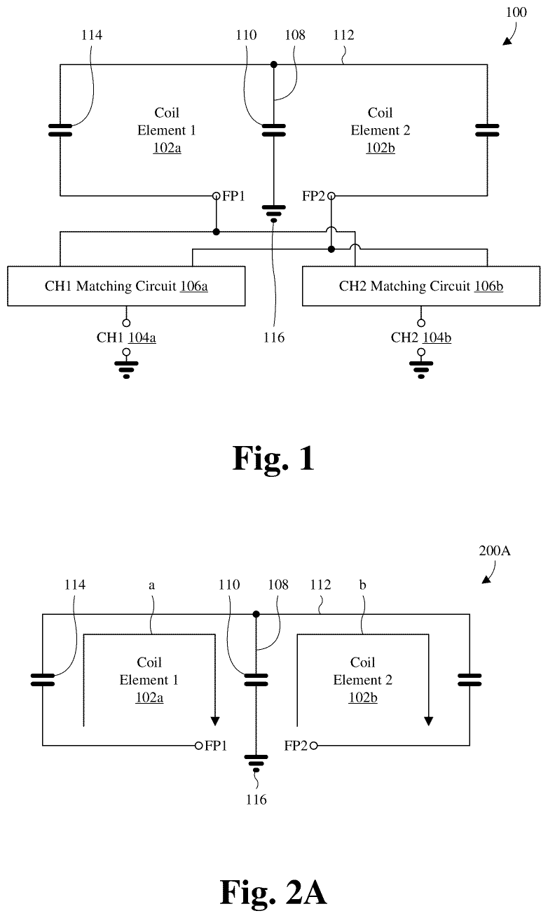

With reference to FIG. 1, a diagram 100 of some embodiments of an MRI RF coil comprising a multi-element channel structure is provided. The MRI RF coil may, for example, correspond to a phased array coil or the like. A first coil element 102a and a second coil element 102b border each other and are each is electrically coupled to a first channel 104a and to a second channel 104b via a first matching circuit 106a and a second matching circuit 106b.

As used herein, a coil element is all conductive traces and all breaking point capacitors that make a resonant path of the coil element. Such a coil element does not include the matching circuit. Further, as used herein, a channel is the RF port right after a matching circuit, where the other end of the matching circuit is electrically coupled to a coil element. The RF port can connect to a preamplifier to create a Rx coil channel in Rx mode or connect to a transmit/receive (T/R) switch to create a Tx/Rx coil channel.

For some phased array coils, channel and coil element may be used interchangeably because there is a one-to-one correspondence between coil element and channel. However, in the present disclosure, channels and coil elements are differentiated because there is no longer a one-to-one correspondence. A channel corresponds to multiple coil elements.

The first and second coil elements 102a, 102b are loop type, but other types are amenable. For example, one or both of the first and second coil elements 102a, 102b may be saddle type. Further, the first and second coil elements 102a, 102b share a shared conductive path 108 along which a decoupling capacitor 110 is arranged and have individual conductive paths 112 along which individual capacitors 114 are arranged.

The decoupling capacitor 110 may, for example, facilitate decoupling of mutual inductance between the first and second coil elements 102a, 102b. In alternative embodiments, the shared conductive path 108 and the decoupling capacitor 110 are omitted, such that the first and second coil elements share no conductive path. In some of such alternative embodiments, the first and second coil elements 102a, 102b may partially overlap to achieve decoupling. The individual capacitors 114 may, for example, correspond to breaking point capacitors, tuning capacitors, some other suitable capacitor type, or a combination of the foregoing.

The conductive paths (shared and individual) correspond to conductive traces and define individual inductances of the first and second coil elements 102a, 102b. These individual inductances resonate with capacitances of the first and second coil elements 102a, 102b at a Larmor frequency or some other suitable working frequency.

The first matching circuit 106a is electrically coupled from the first channel 104a to a feed point FP1 of the first coil element 102a (e.g., the first feed point FP1) and also to a feed point FP2 of the second coil element 102b (e.g., the second feed point FP2). Further, the second matching circuit 106b is electrically coupled from the second channel 104b to the feed point FP1 of the first coil element 102a and also to the feed point FP2 of the second coil element 102b. The first and second feed points FP1, FP2 provide locations at which to inject or control currents in the first and second coil elements 102a, 102b. Further, the first and second feed points FP1, FP2 may also be known as coil matching points or the like.

The first and second matching circuits 106a, 106b are configured to match the first and second coil elements 102a, 102b simultaneously to each of the first and second channels 104a, 104b. Such matching may, for example, be performed to present a 50-ohm impedance or some other suitable impedance at the first and second channels 104a, 104b.

Further, the first and second matching circuits 106a, 106b are configured to promote current patterns in the first and second coil elements 102a, 102b that yield isolation between the first and second channels 104a, 104b. As an example of such current patterns, suppose a current pattern of the first channel 104a is represented as a first vector <a, b> and a current pattern of the second channel 104b is represented as a second vector <c, d>, where a and b are currents of the first channel 104a respectively in the first and second coil elements 102a, 102b, and c and d are currents of the second channel 104b respectively in the first and second coil elements 102a, 102b. Isolation may then be achieved when the dot product of the two current-pattern vectors is zero and hence the two current patterns are orthogonal to each other.

Further, the first and second matching circuits 106a, 106b are configured to promote current patterns in the first and second coil elements 102a, 102b that cause opposing currents in the shared conductive path 108 between the first and second coil elements 102a, 102b. This current cancels to create a virtual ground 116 at the shared conductive path 108.

The isolation between the first and second channels 104a, 104b enables a quadrature mode of operation. Further, because current flow at the shared conductive path 108 is effectively zero, noise from the shared conductive path 108 (e.g., coil-only noise, especially relevant when coil elements are small or operating at 1.5 T and below) may be reduced. Collectively, this may improve SNR. Further, because current flow at the shared conductive path 108 is effectively zero, the dark area that may otherwise be found under the shared conductive path 108, if the shared conductive path 108 extends perpendicular to the B₀ direction, is eliminated.

As seen hereafter, the first and second matching circuits 106a, 106b may achieve the foregoing current patterns and matching by adjusting intrinsic impedances and phase shifts of the first and second matching circuits 106a, 106b. In some embodiments, the first matching circuit 106a applies +90° phase shifts from the first channel 104a to the first and second coil elements 102a, 102b, whereas the second matching circuit 106b applies a +90° phase shift and a −90° phase shift from the second channel 104b respectively to the first and second coil elements 102a, 102b. The first and second matching circuits 106a, 106b may, for example, be or comprise quarter wavelength transformers or some other suitable circuits.

While not shown, in some embodiments, preamplifiers may be electrically coupled to the first and second channels 104a, 104b, whereby each of these preamplifiers may be connected to two coil elements. The preamplifiers may, for example, provide preamplifier decoupling of the first and second coil elements 102a, 102b. In such a configuration, the low input impedance of each preamplifier is transformed, via the first and second matching circuits 106a, 106b, to a high impedance at the feed points FP1, FP2 of the first and second coil elements 102a, 102b, thereby minimizing current flow in each coil element and reducing mutual coupling.

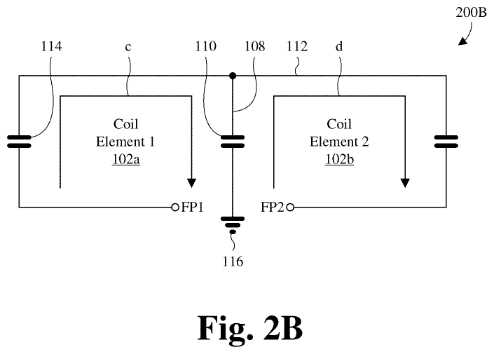

With reference to FIGS. 2A and 2B, diagrams 200A, 200B of some embodiments of current patterns for the first and second channels 104a, 104b of FIG. 1 are provided. FIG. 2A corresponds to a current pattern for the first channel 104a of FIG. 1, whereas FIG. 2B corresponds to a current pattern for the second channel 104b of FIG. 1.

The first and second channels 104a, 104b may drive both the first and second coil elements 102a, 102b simultaneously. The difference between the channels is that the first channel 104a generates current a in the first coil element 102a and current b in the second coil element 102b (see FIG. 2A), while the second channel 104b generates current c in the first coil element 102a and current d in the second coil element 102b (see FIG. 2B). Currents in the first and second coil elements 102a, 102b may be considered independent from each other using this definition. Thus, Eq. 1 may be used to describe the currents.

$$\{ \begin{matrix}\vec{{I}_{1}} = a \hat{ι} + b \hat{𝒿} \\ \vec{{I}_{2}} = c \hat{ι} + d \hat{𝒿}\end{matrix} \qquad Eq . 1$$

With Eq. 1, î is the current vector basis of the first coil element 102a and j is the current vector basis of the second coil element 102b. Since the first and second channels 104a, 104b should be independent channels to achieve a proper phased array coil, good isolation between the first and second channels 104a, 104b is important. Therefore, the dot product of vectors \vec{I₁} and \vec{I₂} should be zero. This yields Eq. 2.

$$\vec{{I}_{1}} \cdot \vec{{I}_{2}} = ac + bd = 0 \qquad Eq . 2$$

What this means is that the first and second channels 104a, 104b may operate independently of each other as long as their currents satisfy Eq. 2. To understand Eq. 2 in detail, and how SNR may be boosted at deep areas, the signal and noise of three special cases may be evaluated using the reciprocal law (e.g., if a current pattern is applied in Tx mode, evaluate the generated B₁ field and coil loss to predict SNR in Rx mode).

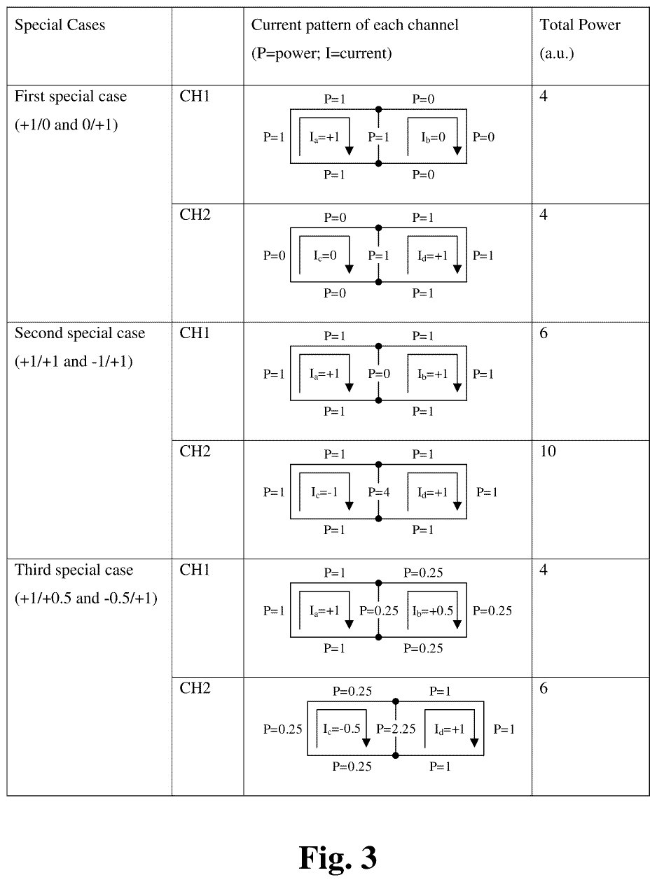

The three special cases are summarized in FIG. 3 and described in detail hereafter. To simplify evaluation, assume that the first and second coil elements 102a, 102b are square, and the resistive loss of each side of the coil elements is identical, with a value of one arbitrary unit (a.u.). Further, note that arbitrary units are used hereafter for the values of a-d and the power values described with regard to the special cases. These arbitrary units are relative to each other and enable comparison of current patterns and power dissipation across the special cases. Further, note that the special cases represent only a few possible solutions to Eq. 2. There may be infinitely many solutions (e.g., one can create infinitely many possible current patterns for good isolation between the first and second channels 104a, 104b).

The first special case is defined by a=+1, b=0 for the first channel 104a and c=0, d=+1 for the second channel 104b. The current pattern of the first channel 104a is such that current flows exclusively through the first coil element 102a, with no current in the second coil element 102b. Similarly, the current pattern of the second channel 104b is such that current flows exclusively through the second coil element 102b, with no current in the first coil element 102a. These current patterns match those of a traditional two-loop phased array coil, where each channel drives only one coil element independently. Hence, the combined B₁ field at deep areas equals that of a large loop. Further, the first special case may also be regarded as the baseline case upon which the present disclosure improves.

In some embodiments, the first channel 104a operates with 4 a.u. of power, and the second channel 104b also operates with 4 a.u. of power, for a total power of 8 a.u. For the first channel 104a, the entire 4 a.u. is dissipated along the four side segments of the first coil element 102a, with equal current magnitude (e.g., 1 a.u.) per segment. Similarly, for the second channel 104b, the entire 4 a.u. is dissipated along the four side segments of the second coil element 102b, with equal current magnitude (e.g., 1 a.u.) per segment.

The second special case is defined by a=+1, b=+1 for the first channel 104a and c=−1, d=+1 for the second channel 104b. The current pattern of the first channel 104a drives both the first and second coil elements 102a, 102b in-phase, forming a “large loop” current pattern. The current pattern of the second channel 104b drives the first and second coil elements 102a, 102b out-of-phase, forming a “saddle” current pattern. Hence, the B₁ field of the first channel 104a matches that of a large loop, while the B₁ field of the second channel 104b is perpendicular to it. The second special case corresponds to a current pattern that may be used with FIG. 1 to improve upon the baseline.

In some embodiments, the first channel 104a operates with 6 a.u. of power, and the second channel 104b operates with 10 a.u. of power, for a total power of 16 a.u. For the first channel 104a, the power is distributed such that the 6 a.u. is dissipated along all six outer side segments of the two coil elements (three per coil element), with equal current magnitude (e.g., 1 a.u.) per segment. No power is dissipated along the shared inner segment. For the second channel 104b, the 10 a.u. is dissipated such that 6 a.u. is dissipated along the six outer side segments of the two coil elements (three per coil element), with equal current magnitude (e.g., 1 a.u.) per segment. Further, 4 a.u. is dissipated along the shared inner segment.

The first channel 104a by itself produces the same combined B₁ field as the first and second channels 104a, 104b collectively produced in the first special case (e.g., the baseline), but does so with only 6 a.u. of power instead of 8 a.u. Hence, the first channel 104a in the second special case is more power-efficient than the baseline. Further, because the B₁ field of the second channel 104b is orthogonal to the B₁ field of the first channel 104a, quadrature reception is enabled and may boost SNR at deep areas beyond the baseline.

The third special case is defined by a=+1, b=+½ for the first channel 104a and c=−½, d=+1 for the second channel 104b. The current pattern of the first channel 104a drives the first coil element 102a with a=+1 and the second coil element 102b with b=+½. The current pattern of the second channel 104b drives the first coil element 102a with c=−½ and the second coil element 102b with d=+1. The resulting B₁ field is a vector sum: one unit of the “large loop” B₁ field from the first channel 104a of the second special case, plus half a unit of the “saddle” B₁ field from the second channel 104b of the second special case.

In some embodiments, the first channel 104a operates with 4 a.u. of power, and the second channel 104b operates with 6 a.u. of power, for a total power of 10 a.u. For the first channel 104a, the power is distributed such that 3 a.u. is dissipated along the three outer side segments of the first coil element 102a and 1 a.u. is dissipated along the shared inner segment and the three outer side segments of the second coil element 102b. The 3 a.u. is dissipated with equal current magnitude (e.g., 1 a.u.) per segment, and the 1 a.u. is dissipated with equal current magnitude (e.g., 0.25 a.u.) per segment. For the second channel 104b, the 6 a.u. is dissipated such that 0.75 a.u. is dissipated along the three outer side segments of the first coil element 102a, 3 a.u. is dissipated along the three outer side segments of the second coil element 102b, and 2.25 a.u. is dissipated along the shared inner segment. The 0.75 a.u. is dissipated with equal current magnitude (e.g., 0.25 a.u.) per segment, and the 3 a.u. is dissipated with equal current magnitude (e.g., 1 a.u.) per segment.

The third special case is more complicated than the first two special cases but offers a middle ground between them. It achieves an SNR that is better than the SNR of the first special case, but worse than the SNR of the second special case. However, it is also more power-efficient compared to the second special case. The third special case corresponds to another current pattern that may be used with FIG. 1 to improve upon the baseline.

As seen with the three special cases, summarized in the table of FIG. 3, the first special case (e.g., the traditional phased array) yields poor SNR at deep areas. However, using two or more coil elements as one channel simultaneously (e.g., the second and third special cases) may provide an SNR boost at deep areas. Further, it can be seen that the SNR benefit arises from two factors. The first factor is that current flow through the shared coil path is reduced to avoid redundant or noise-generating current patterns. This, in turn, reduces current loss at the shared coil path without sacrificing signal. The second factor is that significantly more quadrature signal reception than in the first special case is introduced.

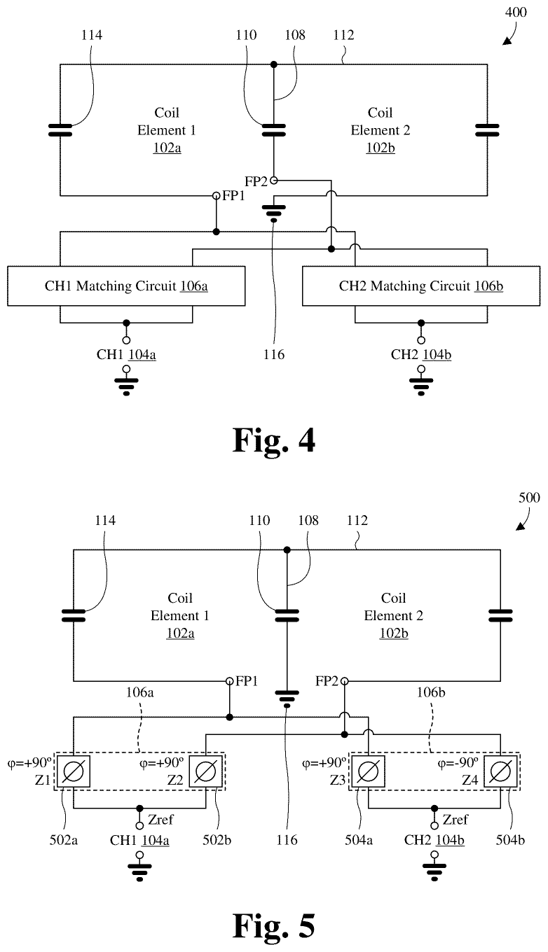

With reference to FIG. 4, a diagram 400 of some alternative embodiments of the MRI RF coil of FIG. 1 is provided in which the second feed point FP2 is shifted to the shared conductive path 108. In yet other alternative embodiments, the first feed point FP1 may be shifted to the shared conductive path 108 and the second feed point FP2 may be as in FIG. 1.

With reference to FIG. 5, a diagram 500 of some embodiments of the MRI RF coil of FIG. 1 is provided in which the first and second matching circuits 106a, 106b comprise phase shifters to achieve the aforementioned current patterns.

The first matching circuit 106a comprises a first first-channel phase shifter 502a (e.g., X1) and a second first-channel phase shifter 502b (e.g., X2) that are electrically coupled from the first channel 104a respectively to the feed point FP1 of the first coil element 102a and the feed point FP2 of the second coil element 102b. The first and second first-channel phase shifters 502a, 502b are both +90 degree phase shifters (e.g., φ=+90°) and respectively have a first intrinsic impedance Z1 and a second intrinsic impedance Z2.

The second matching circuit 106b comprises a first second-channel phase shifter 504a (e.g., X2) and a second second-channel phase shifter 504b (e.g., X4) that are electrically coupled from the second channel 104b respectively to the feed point FP1 of the first coil element 102a and the feed point FP2 of the second coil element 102b. The first and second second-channel phase shifters 504a, 504b are respectively a +90 degree phase shifter (e.g., φ=+90°) and a −90 degree phase shifter (e.g., φ=−90°). Further, the first and second second-channel phase shifters 504a, 504b respectively have a third intrinsic impedance Z3 and a fourth intrinsic impedance Z4.

In alternative embodiments, the first and second first-channel phase shifters 502a, 502b and/or the first and second second-channel phase shifters 504a, 504b may have other suitable phase shifts to achieve channel isolation. For example, the first and second second-channel phase shifters 504a, 504b may respectively have a −90 degree phase shift (e.g., φ=−90°) and a +90 degree phase shift (e.g., φ=+90°.

The first and second first-channel phase shifters 502a, 502b may or may not be of the same type, and the first and second second-channel phase shifters 504a, 504b may or may not be of the same type. As described below, suitable types of phase shifters include quarter wavelength transformers (e.g., “T” and “π” phase shifters) or the like.

For the first and second channels 104a, 104b to have good isolation, the intrinsic impedances (e.g., Z1, Z2, Z3, Z4) of the various phase shifters (e.g., 502a, 502b, 504a, 504b) are such that currents passing through the phase shifters to/from the coil elements satisfy the orthogonality condition described in Eq. 2 (e.g., ac+bd=0). Here, the first and second first-channel phase shifters 502a, 502b correspond to currents a and b, while the first and second second-channel phase shifters 504a, 504b correspond to currents c and d.

Further, the intrinsic impedances are such that the signal from the first channel 104a (e.g., P1) traveling through the first first-channel phase shifter 502a and the first second-channel phase shifter 504a cancels the signal from the first channel 104a traveling through the second first-channel phase shifter 502b and the second second-channel phase shifter 504b. In other words, the intrinsic impedances are such that these two signal paths have opposite phases and similar magnitudes. This cancellation of the two signals ensures that the first and second channels 104a, 104b exhibit good isolation even before connecting to the coil elements.

Further yet, the intrinsic impedances are such that the various phase shifters (e.g., 502a, 502b, 504a, 504b) match the first and second channels 104a, 104b to the first and second coil elements 102a, 102b. For example, supposing the first and second channels 104a, 104b expect an impedance Zref (e.g., 50 ohms), the various phase shifters may translate impedances of the first and second coil elements 102a, 102b to the expected impedance Zref at the first and second channels 104a, 104b.

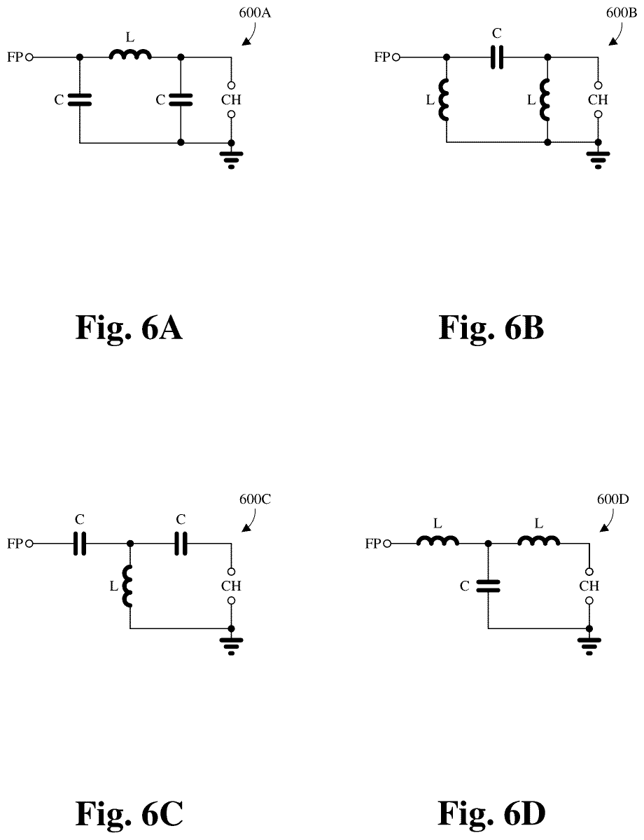

With reference to FIGS. 6A-6D, diagrams 600A-600D of some embodiments of different types of “π” and “T” phase shifters for use as the various phase shifters (e.g., 502a, 502b, 504a, 504b) of FIG. 5 are provided. As noted above, the various phase shifters (e.g., 502a, 502b, 504a, 504b) of FIG. 5 may be of the same type or of different types.

Focusing on the diagram 600A of FIG. 6A, a low-pass “π” phase shifter is provided in which an inductor L is electrically coupled from a feed point FP to a channel CH. Further, a pair of capacitors C are electrically coupled on opposite sides of the inductor L, each electrically coupled between the signal path and the return path.

Focusing on the diagram 600B of FIG. 6B, a high-pass “π” phase shifter is provided in which a capacitor C is electrically coupled from a feed point FP to a channel CH. Further, a pair of inductors L are electrically coupled on opposite sides of the capacitor C and are each electrically coupled between the signal path and the return path.

Focusing on the diagram 600C of FIG. 6C, a high-pass “T” phase shifter is provided in which a pair of capacitors C are electrically coupled from a common node respectively to a feed point FP and a channel CH. Further, an inductor L is electrically coupled to the common node, from the signal path to the return path.

Focusing on the diagram 600D of FIG. 6D, a low-pass “T” phase shifter is provided in which a pair of inductors L are electrically coupled from a common node respectively to a feed point FP and a channel CH. Further, a capacitor C is electrically coupled to the common node, from the signal path to the return path.

The different types of phase shifters in FIGS. 6A-6D may all be regarded as quarter wavelength transformers or phase shifters. Further, within each of FIGS. 6A-6D, the feed point FP may, for example, correspond to the first or second feed point FP1, FP2 of FIG. 5 and/or the channel CH may, for example, correspond to the first or second channel 104a, 104b of FIG. 5. Further yet, the low-pass phase shifters (e.g., FIGS. 6A and 6D) may, for example, be employed for +90° phase shifts, whereas the high-pass phase shifters (e.g., FIGS. 6B and 6C) may, for example, be employed for −90° phase shifts.

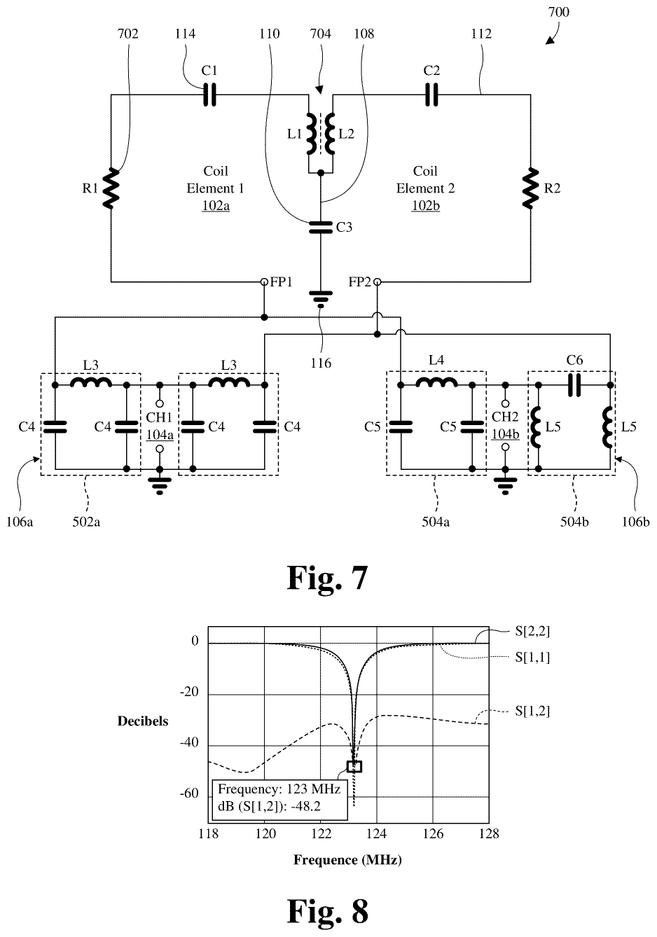

With reference to FIG. 7, a diagram 700 of some embodiments of the MRI RF coil of FIG. 5 is provided in which the various phase shifters are shown as “π” phase shifters as in FIGS. 6A and 6B. Further, the first and second coil elements 102a, 102b are shown with an equivalent circuit representation for use with an S-parameter simulation.

The first and second coil elements 102a, 102b comprise individual capacitors 114 (also labeled C1 and C2), individual partial loop resistances 702 (also labeled R1 and R2), and a transformer 704, and further share a decoupling capacitor 110 (also labeled C3). The transformer 704 represents the individual inductances L1, L2 of the first and second coil elements 102a, 102b, as well as the mutual inductance between the first and second coil elements 102a, 102b and partial resistive losses of the transformer 704.

In some embodiments, individual inductances L1 and L2 are 194.2 nanohenries (nH), the coupling coefficient of the transformer 704 is 0.1, and the partial resistive losses of the transformer 704 are 0.2 ohms. In some embodiments, capacitors C1 and C2 have individual capacitances of 9.55 picofarads (pF), and the partial loop resistances R1 and R2 are 1 ohm. In some embodiments, capacitor C3 has a capacitance of 86 pF. Notwithstanding these specific values, other suitable values are amenable in alternative embodiments.

The first and second first-channel phase shifters 502a, 502b are both low-pass “π” phase shifters as in FIG. 6A, and the first and second second-channel phase shifters 504a, 504b are respectively a low-pass “π” phase shifter as in FIG. 6A and a high-pass “π” phase shifter as in FIG. 6B. Other suitable types of phase shifter may, however, be employed.

The first and second first-channel phase shifters 502a, 502b each comprise a pair of capacitors C4 and an inductor L3. The first second-channel phase shifter 504a comprises a pair of capacitors C5 and an inductor L4, and the second second-channel phase shifter 504b comprises a pair of inductors L5 and a capacitor C6.

In some embodiments, capacitors C4 are 74.3 pF, inductors L3 are 22.6 nH, capacitors C5 are 138.8 pF, inductor L4 is 12.1 nH, capacitor C6 is 208.3 pF, and inductors L5 are 8 nH. Further, in some embodiments, the various inductors (e.g., L3, L4, and L5) are associated with resistances (e.g., of 0.07 ohms). Notwithstanding these specific values, other suitable values are amenable in alternative embodiments.

With reference to FIG. 8, a graph of some embodiments of results for an S-parameter simulation using the MRI RF coil of FIG. 7 is provided. The graph plots S-parameters in decibels as a function of frequency in megahertz (MHz). The S-parameter simulation was performed using the specific capacitance, inductance, and resistance values described above. Further, the S-parameter simulation was performed using a linear S-parameter sweep from 118 MHz to 128 MHz with 5001 frequency points.

A first curve represents S[1,1], a second curve represents S[2,2], and a third curve represents S[1,2]. S[1,1] and S[2,2] correspond respectively to the reflection coefficients at the first and second channels 104a, 104b. S[1,2] corresponds to the transmission coefficient (e.g., mutual coupling) between the first and second channels 104a, 104b.

The S-parameters shown confirm that the dual-channel, dual-element coil design achieves strong isolation at the working frequency of approximately 123 MHz. S[1,1] and S[2,2] both remain near 0 dB across the frequency range, with narrow dips near the working frequency, consistent with high impedance conditions at the first and second channels 104a, 104b due to preamplifier decoupling. S[1,2] shows a deep null of approximately −48.2 dB at the working frequency, confirming strong isolation between the first and second channels 104a, 104b and effective decoupling between the first and second coil elements 102a, 102b.

The S-parameter simulation validates that a single coil channel can be generated from two coil elements rather than a single coil element. Further, the use of quarter wavelength phase shifters enables high-impedance preamplifier decoupling at both feed points when low-input-impedance preamplifiers are employed at the first and second channels 104a, 104b. With this strong isolation and matching preserved, the MRI RF coil of the present disclosure behaves functionally the same as a traditional phased array coil.

With reference to FIG. 9, a diagram 900 of some alternative embodiments of the MRI RF coil of FIG. 7 is provided in which the second feed point FP2 is shifted to the shared conductive path 108. In yet other alternative embodiments, the first feed point FP1 may be shifted to the shared conductive path 108 and the second feed point FP2 may be as in FIG. 7.

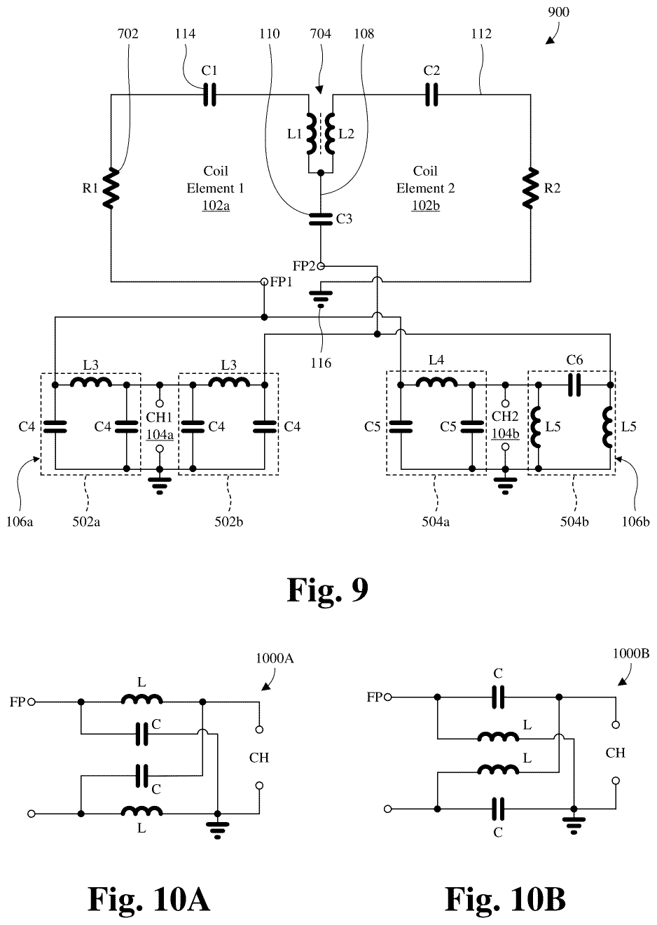

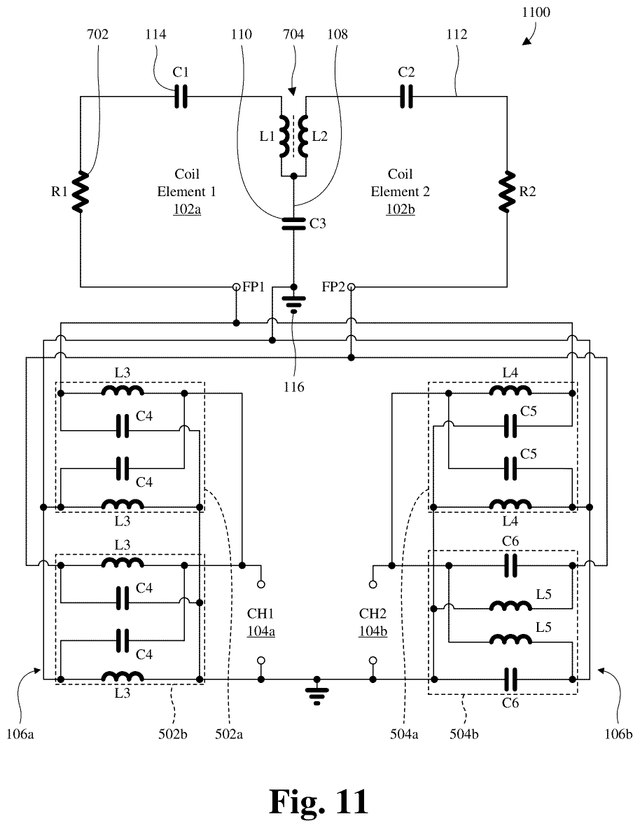

With reference to FIGS. 10A and 10B, diagrams 1000A, 1000B of some embodiments of different types of lattice baluns for use as the various phase shifters (e.g., 502a, 502b, 504a, 504b) of FIG. 5 are provided. Use of lattice baluns in place of “π” and “T” phase shifters eliminates the need for additional cable baluns near the first and second channels 104a, 104b, thereby reducing the complexity and cost of the MRI RF coil. Further, lattice baluns correspond to another type of quarter wavelength transformer or phase shifter.

Focusing on the diagram 1000A of FIG. 10A, a forward lattice balun is provided. A pair of inductors L are electrically coupled from a channel CH to a port to which the feed point FP is coupled. Further, a pair of capacitors C are each electrically coupled from the channel-side terminal of one inductor L to the feed-point-side terminal of the other inductor L.

Focusing on the diagram 1000B of FIG. 10B, a backward lattice balun is provided. A pair of capacitors C are electrically coupled from a channel CH to a port to which the feed point FP is coupled. Further, a pair of inductors L are each electrically coupled from the channel-side terminal of one capacitor C to the feed-point-side terminal of the other capacitor C.

Within each of FIGS. 10A and 10B, the feed point FP may, for example, correspond to the first or second feed point FP1, FP2 of FIG. 5 and/or the channel CH may, for example, correspond to the first or second channel 104a, 104b of FIG. 5. Further, the forward lattice balun (e.g., 10A) may, for example, be employed for +90° phase shifts, whereas the backward lattice balun (e.g., 10B) may, for example, be employed for −90° phase shifts.

With reference to FIG. 11, a diagram 1100 of some embodiments of the MRI RF coil of FIG. 5 is provided in which the various phase shifters are shown as lattice baluns as in FIGS. 10A and 10B. Further, the first and second coil elements 102a, 102b are shown with an equivalent circuit representation. The equivalent circuit representation may, for example, be as described with regard to FIG. 7.

The first and second first-channel phase shifters 502a, 502b are both forward lattice baluns as in FIG. 10A, and the first and second second-channel phase shifters 504a, 504b are respectively a forward lattice balun as in FIG. 10A and a backward lattice balun as in FIG. 10B. Other suitable types of lattice baluns and/or phase shifters may, however, be employed.

The first and second first-channel phase shifters 502a, 502b each comprise a pair of capacitors C4 and a pair of inductors L3. The first second-channel phase shifter 504a comprises a pair of capacitors C5 and a pair of inductors L4, and the second second-channel phase shifter 504b comprises a pair of inductors L5 and a pair of capacitors C6.

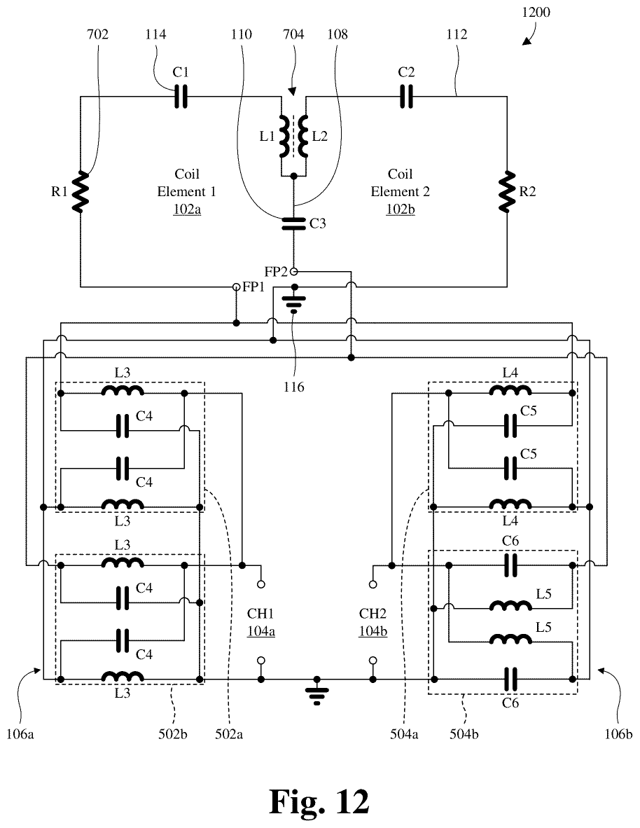

With reference to FIG. 12, a diagram 1200 of some alternative embodiments of the MRI RF coil of FIG. 11 is provided in which the second feed point FP2 is shifted to the shared conductive path 108. In yet other alternative embodiments, the first feed point FP1 may be shifted to the shared conductive path 108 and the second feed point FP2 may be as in FIG. 11.

As described above, the multi-element channel structure disclosed herein reduces noise from inner conductive traces while enabling quadrature-like reception at deep tissue regions, thereby enhancing overall coil SNR. Additional benefits also exist. Parallel imaging capability remains similar to that of traditional phased array coils, because the coil geometry is unchanged and the current pattern of the new approach can be converted back to the traditional coil current pattern via matrix transformation. See, for example, the first special case above.

Another benefit is the elimination of the dark area underneath the shared conductive path (e.g., the shared conductive path 108 in FIG. 1) when that path extends perpendicular to the direction of the B₀ field. In traditional phased array coils, the shared conductive path functions as each channel's coil edge. When the B₁ field generated by the edge current aligns with the B₀ field, a dark area appears underneath the edge due to minimal contribution from the opposing coil edge, which is distant and thus electromagnetically decoupled. In contrast, for the multi-element channel structure, the shared conductive path is no longer an edge of each channel. Instead, it is at the center of each channel. The outer coil edges now contribute signal underneath the shared path, effectively eliminating the dark area. Consequently, coil elements may be arranged along both x and y dimensions without concern for dark areas. Note that the x and y dimensions correspond to Cartesian coordinates of the plane in which the earlier figures are illustrated, and the x dimension may correspond to the B₀ direction in some embodiments.

Another benefit is the reduction in the number of cable baluns. In a traditional phased array coil, each channel electrically couples to one coil element and maintains its own virtual ground. To prevent ground-loop interference between channels, a separate cable balun may be employed for each channel. As a result, a traditional two-channel phased array coil may depend on two cable baluns. In contrast, with the multi-element channel structure, all channels share a common coil virtual ground to maintain mutual isolation and matching. As a result, a single cable balun may be sufficient for all channels after matching.

Another benefit is that the multi-element channel structure is not limited to loop-type coil elements. The multi-element channel structure can be used with a loop-type coil element and a saddle-type coil element, or with two saddle-type coil elements. Further, the orientation and layout of the coil elements is flexible. The coil elements do not need to align with each other. Coil elements may have an offset between them. Additionally, the coil elements do not need to be arranged along only one direction (e.g., an x direction). Coil elements may also be arranged along their perpendicular direction (e.g., a y direction). As noted above, x and y dimensions correspond to Cartesian coordinates of the plane in which the earlier figures are illustrated, and the x dimension may correspond to the B₀ direction in some embodiments.

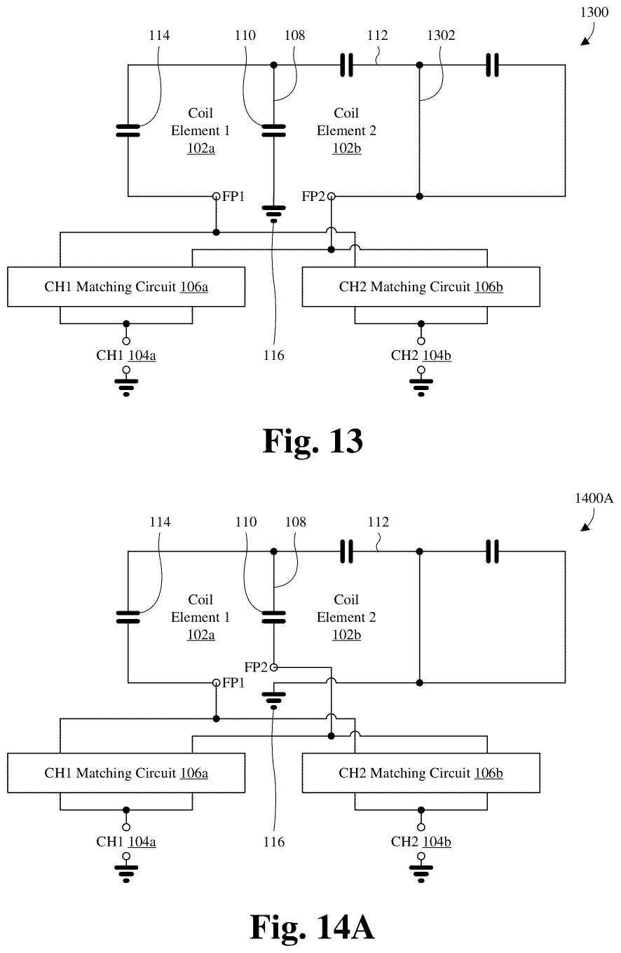

With reference to FIG. 13, a diagram 1300 of some alternative embodiments of the MRI RF coil of FIG. 1 is provided in which the second coil element 102b is saddle type and the first coil element 102a is loop type. Hence, the second coil element 102b has a pair of loops sharing a conductive path 1302. Further, although the pair of loops of the second coil element 102b are shown in a common plane in FIG. 13, in practice the pair of loops may be arranged on opposite sides of an imaging volume. In alternative embodiments, the first coil element 102a may instead be saddle type and the second coil element may be loop type.

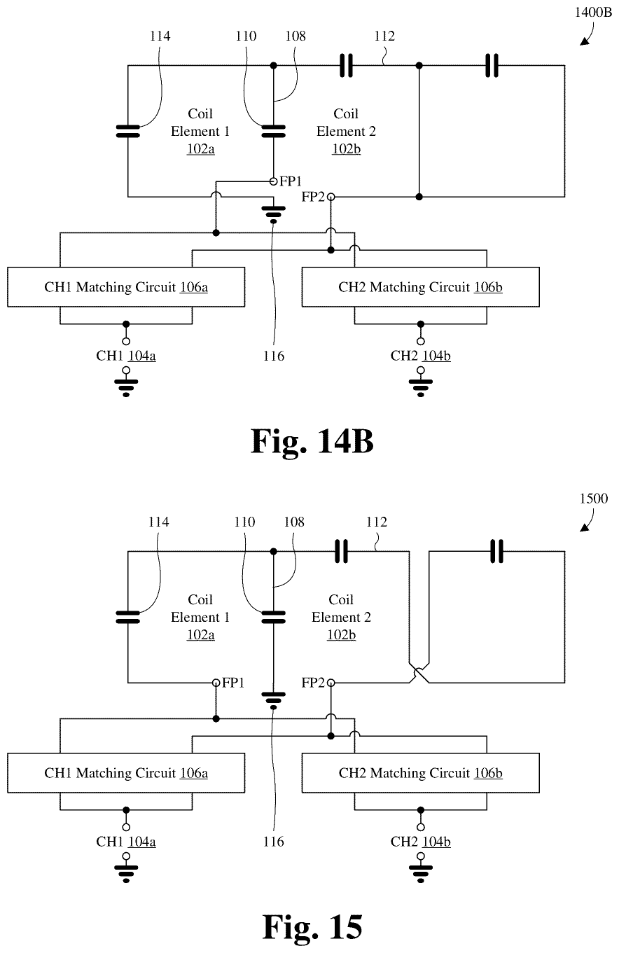

With reference to FIGS. 14A and 14B, diagrams 1400A, 1400B of some alternative embodiments of the MRI RF coil of FIG. 13 are provided in which feed points are varied. In FIG. 14A, the second feed point FP2 is shifted to the shared conductive path 108. In FIG. 14B, the first feed point FP1 is shifted to the shared conductive path 108.

With reference to FIG. 15, a diagram 1500 of some alternative embodiments of the MRI RF coil of FIG. 13 is provided in which the second coil element 102b has a figure-eight type configuration instead of a pair of loops sharing a conductive path. In alternative embodiments, the second coil element 102b may have some other suitable saddle-type configuration.

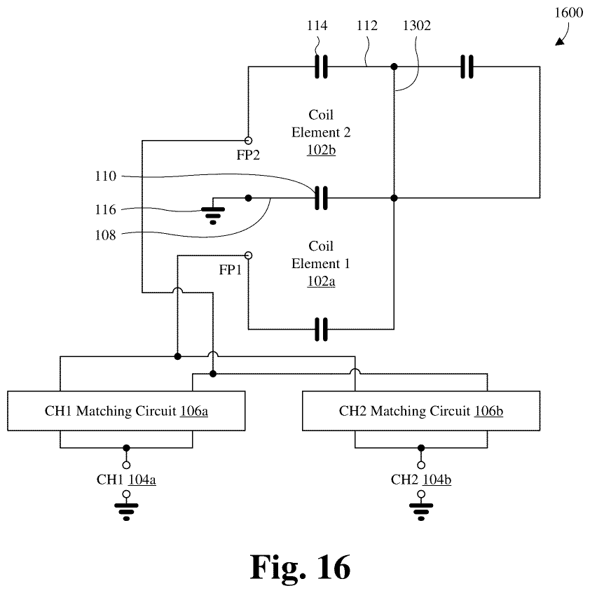

With reference to FIG. 16, a diagram 1600 of some alternative embodiments of the MRI RF coil of FIG. 13 is provided in which the relative positioning between the first and second coil elements 102a, 102b is varied. For example, the first and second coil elements 102a, 102b may border each other in the y dimension (e.g., top to bottom) in the plane in which FIG. 16 is illustrated. This is to be contrasted with FIG. 13, where the first and second coil elements 102a and 102b border each other in the x dimension (e.g., left to right) in the plane in which FIG. 13 is illustrated. In some embodiments, the x dimension may correspond to the B₀ direction during imaging, whereas the y dimension may be perpendicular to B₀ during imaging.

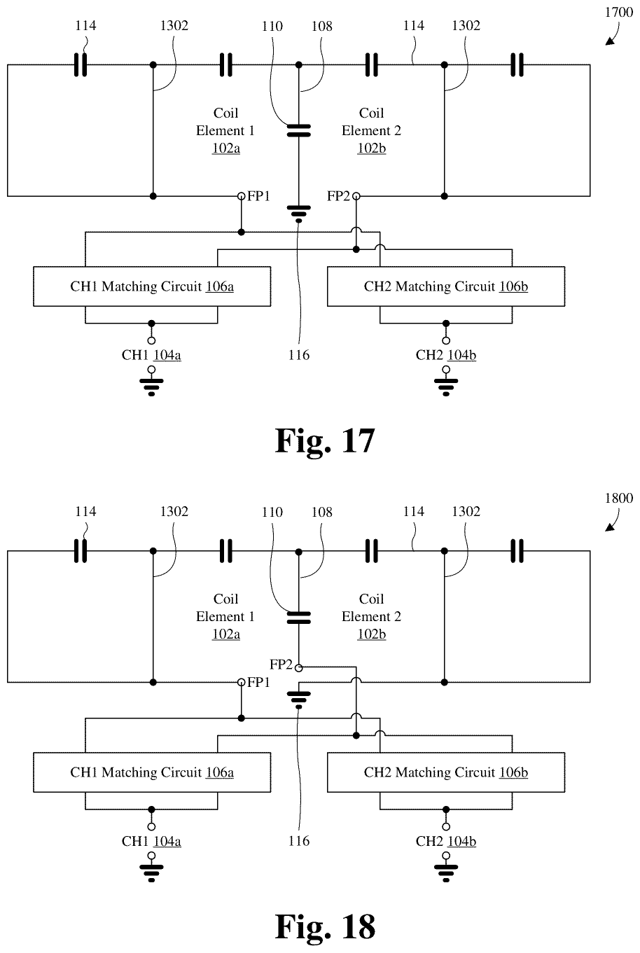

With reference to FIG. 17, a diagram 1700 of some alternative embodiments of the MRI RF coil of FIG. 1 is provided in which the first and second coil elements 102a, 102b are both saddle type. Hence, the first and second coil elements 102a, 102b each comprise a pair of loops sharing a respective conductive path 1302. Further, although the pairs of loops are shown in a common plane in FIG. 17, in practice each pair of loops may be arranged on opposite sides of an imaging volume.

With reference to FIG. 18, a diagram 1800 of some alternative embodiments of the MRI RF coil of FIG. 17 is provided in which the second feed point FP2 is shifted to the shared conductive path 108. In alternative embodiments, instead of the second feed point FP2 being shifted to the shared conductive path 108, the first feed point FP1 may be shifted to the shared conductive path 108.

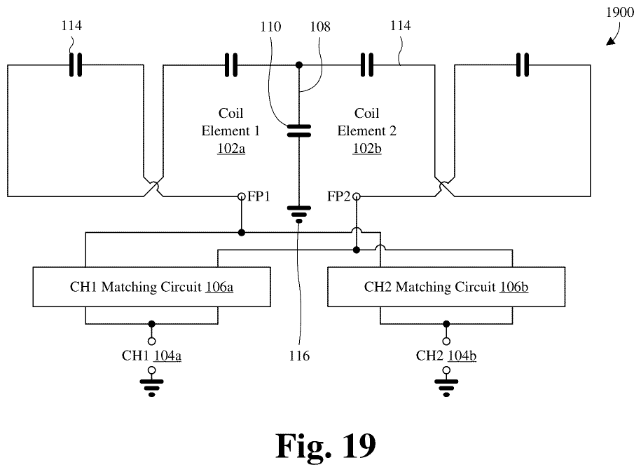

With reference to FIG. 19, a diagram 1900 of some alternative embodiments of the MRI RF coil of FIG. 17 is provided in which the first and second coil elements 102a, 102b have a figure-eight type configuration. This is to be contrasted with the configuration seen for the first and second coil elements 102a, 102b in FIG. 17.

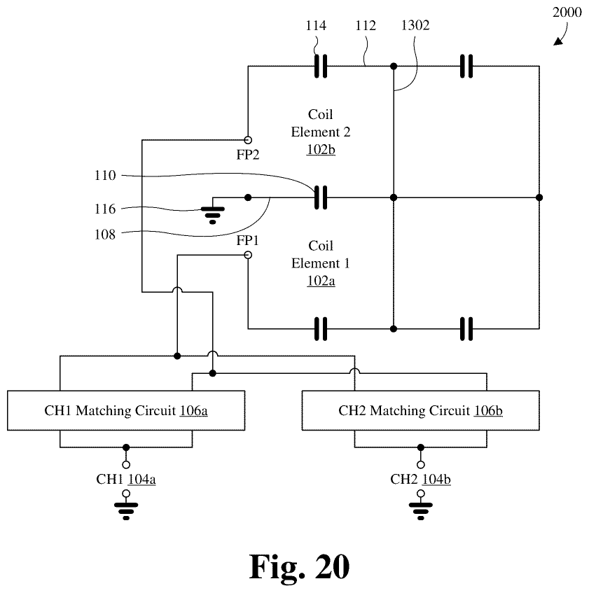

With reference to FIG. 20, a diagram 2000 of some alternative embodiments of the MRI RF coil of FIG. 17 is provided, in which the relative positioning between the first and second coil elements 102a, 102b is varied. For example, the first and second coil elements 102a, 102b may border each other in the y dimension (e.g., top to bottom) in the plane in which FIG. 20 is illustrated. This is to be contrasted with FIG. 17, where the first and second coil elements 102a and 102b border each other in the x dimension (e.g., left to right) in the plane in which FIG. 17 is illustrated. In some embodiments, the x dimension may correspond to the B₀ direction during imaging, whereas the y dimension may be perpendicular to B₀ during imaging.

While FIGS. 13 to 20 generally illustrate the first and second matching circuits 106a, 106b, it is to be appreciated that the first and second matching circuits may be as in any of FIGS. 5, 7, and 9-12. While FIGS. 14A, 14B, 16, 18, and 20 illustrate certain saddle-type configurations, it is to be appreciated that other saddle-type configurations are amenable. For example, the figure-eight saddle-type configuration may be employed. While FIGS. 16, 19, and 20 are illustrated with a non-shared-non-shared feed point configuration, it is to be appreciated that alternative feed point configurations are amenable. For example, FIG. 16 may have a non-shared-shared feed point configuration as in FIG. 14A or a shared-non-shared configuration as in FIG. 14B. As another example, FIGS. 19 and 20 may have a non-shared-shared feed point configuration as in FIG. 18 or a shared-non-shared configuration.

Thus far, the focus has been on a multi-element channel structure with two coil elements per channel. However, there may be three or more coil elements per channel.

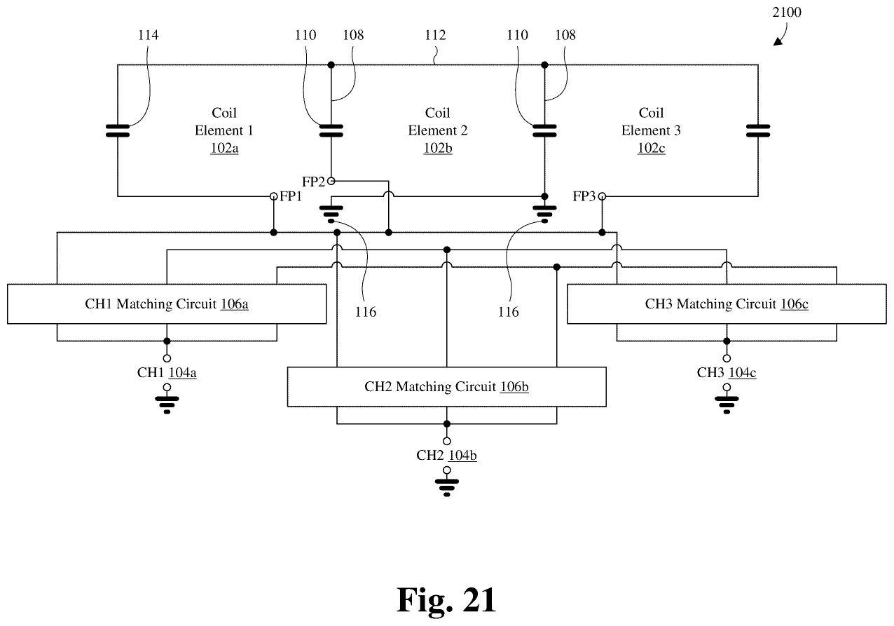

With reference to FIG. 21, a diagram 2100 of some alternative embodiments of the MRI RF coil of FIG. 1 is provided in which the multi-element channel structure further comprises a third coil element 102c, a third channel 104c, and a third matching circuit 106c. The third coil element 102c borders the second coil element 102b on an opposite side of the second coil element 102b as the first coil element 102a.

The first, second, and third coil elements 102a-102c (collectively the coil elements 102a-102c) have individual conductive paths 112 along which individual capacitors 114 are arranged. Further, between each neighboring pair of coil elements (e.g., the first and second coil elements 102a, 102b and the second and third coil elements 102b, 102c) is a shared conductive path 108 along which a decoupling capacitor 110 is arranged.

The conductive paths (shared and individual) correspond to conductive traces and define individual inductances of the coil elements 102a-102c. These individual inductances resonate with capacitances of the coil elements 102a-102c at a Larmor frequency or some other suitable working frequency. Further, the bottom conductive path of the second coil element 102b is devoid of break point capacitors so that the path may serve as virtual ground for all three channels via the three loops. The coil elements 102a-102c are illustrated as loop type, but one, some, or all of the coil elements 102a-102c may be saddle type or some other suitable type.

The first matching circuit 106a is electrically coupled from the first channel 104a to a feed point FP1 of the first coil element 102a (e.g., the first feed point FP1), a feed point FP2 of the second coil element 102b (e.g., the second feed point FP2), and a feed point FP3 of the third coil element 102c (e.g., the third feed point FP3). The second matching circuit 106b is electrically coupled from the second channel 104b to the feed point FP1 of the first coil element 102a, the feed point FP2 of the second coil element 102b, and the feed point FP3 of the third coil element 102c. The third matching circuit 106c is electrically coupled from the third channel 104c to the feed point FP1 of the first coil element 102a, the feed point FP2 of the second coil element 102b, and the feed point FP3 of the third coil element 102c.

The first feed point FP1 is at a non-shared path of the first coil element 102a, the second feed point FP2 is at the shared conductive path 108 between the first and second coil elements 102a, 102b, and the third feed point FP3 is at a non-shared trace of the third coil element 102c. In alternative embodiments, the various feed points may have some other suitable configuration.

The first, second, and third matching circuits 106a-106c employ quarter wavelength phase shifters. For example, the first, second, and third matching circuits 106a-106c may each comprise three individual phase shifters (e.g., one for each coil element). These individual phase shifters may, for example, correspond to “π” phase shifters (e.g., as in FIGS. 6A and 6B), “T” phase shifters (e.g., as in FIGS. 6C and 6D), lattice baluns (e.g., as in FIGS. 10A and 10B), or some other suitable phase shifters. The phase signs and intrinsic impedances of the individual phase shifters are such that all channels are isolated from each other and have good matchings to their corresponding coil elements.

Note that the intrinsic impedance of each phase shifter is affected by loads of coil elements and isolations among coil elements and/or channels. They are often determined when the coil is being built. Further, note that other combinations of loops and saddles for three coil elements are not shown here for the sake of simplicity because there are too many combinations considering loop, saddle, alignment, and offset options.

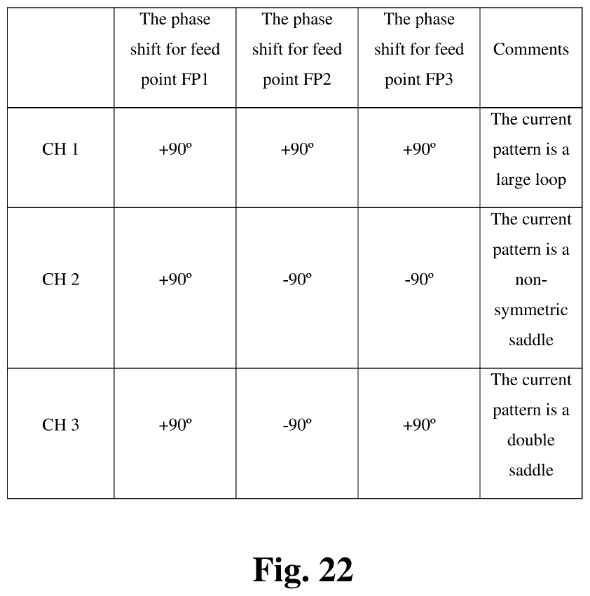

With reference to FIG. 22, a table of some embodiments of phase shifts while matching the first, second, and third channels 104a-104c to each of the first, second, and third coil elements 102a-102c is provided. For example, the first channel 104a is matched to the first, second, and third coil elements 102a-102c respectively with +90°, +90°, +90° phase shifts to achieve a current pattern resembling that of a large loop. The second channel 104b is matched to the first, second, and third coil elements 102a-102c respectively with +90°, −90°, −90° phase shifts to achieve a current pattern resembling that of a non-symmetric saddle. The third channel 104c is matched to the first, second, and third coil elements 102a-102c respectively with +90°, −90°, +90° phase shifts to achieve a current pattern resembling that of a double saddle.

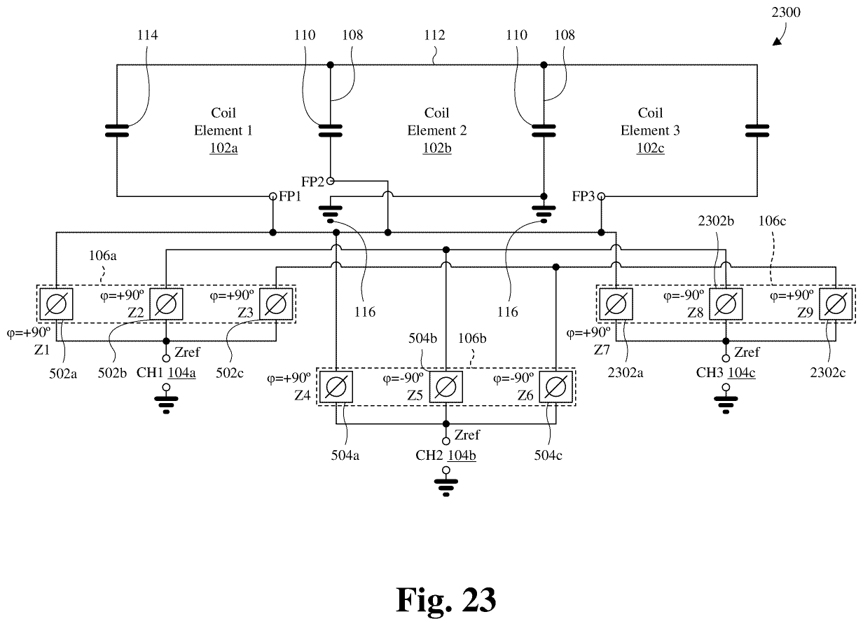

With reference to FIG. 23, a diagram 2300 of some embodiments of the MRI RF coil of FIG. 21 is provided in which the first, second, and third matching circuits 106a-106c each comprise three phase shifters.

The first matching circuit 106a comprises a first first-channel phase shifter 502a (e.g., X1), a second first-channel phase shifter 502b (e.g., X2), and a third first-channel phase shifter 502c (e.g., X3) that are electrically coupled from the first channel 104a respectively to the first, second, and third feed points FP1, FP2, FP3. The first, second, and third first-channel phase shifters 502a-502c are +90 degree phase shifters (e.g., φ=+90°) and respectively have a first intrinsic impedance Z1, a second intrinsic impedance Z2, and a third intrinsic impedance Z3.

The second matching circuit 106b comprises a first second-channel phase shifter 504a (e.g., X4), a second second-channel phase shifter 504b (e.g., X5), and a third second-channel phase shifter 504c (e.g., X6) that are electrically coupled from the second channel 104b respectively to the first, second, and third feed points FP1, FP2, FP3. The first second-channel phase shifter 504a is a +90 degree phase shifter (e.g., φ=+90°) and has a fourth intrinsic impedance Z4. The second and third second-channel phase shifters 504b, 504c are −90 degree phase shifters (e.g., φ=−90°) and respectively have a fifth intrinsic impedance Z5 and a sixth intrinsic impedance Z6.

The third matching circuit 106c comprises a first third-channel phase shifter 2302a (e.g., X7), a second third-channel phase shifter 2302b (e.g., X8), and a third third-channel phase shifter 2302c (e.g., X9) that are electrically coupled from the third channel 104c respectively to the first, second, and third feed points FP1, FP2, FP3. The first and third third-channel phase shifters 2302a, 2302c are +90 degree phase shifters (e.g., φ=+90°) and respectively have a seventh intrinsic impedance Z7 and a ninth intrinsic impedance Z9. The second third-channel phase shifter 2302b is a −90 degree phase shifter (e.g., φ=−90°) and has an eighth intrinsic impedance Z8.

The various phase shifters may or may not be of the same type globally or within a matching circuit. Further, as described below, suitable types of phase shifters include quarter wavelength transformers (e.g., “T” and “T” phase shifters or lattice baluns) or the like.

When one examines FIG. 7 and other figures, the number of matching circuit components (e.g., capacitors and inductors) may be substantial (e.g., FIG. 7 shows twelve capacitors and inductors in the matching circuits). This may appear disadvantageous. However, because many matching components are connected in parallel, some may be combined into a single component. Further, some may be eliminated entirely if the components (e.g., a capacitor and an inductor) resonate together at the working frequency. Additionally, either a “π” or “T” phase shifter (see, e.g., FIGS. 6A-6D) may be selected for each phase shifter to maximize opportunities for further component reduction. Consequently, the total number of components may be significantly reduced for simplified implementation.

In addition to matching circuit components, the number of baluns may be further reduced if two or more coil groups are put together. Each coil group has multiple channels, which share multiple coil elements as described in earlier figures.

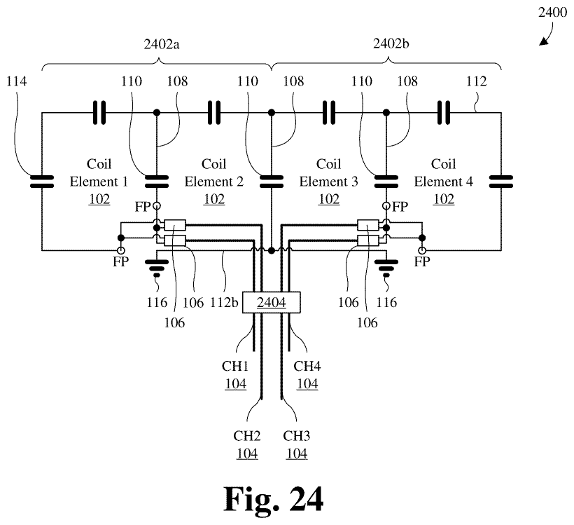

With reference to FIG. 24, a diagram 2400 of some embodiments of an MRI RF coil comprising a first coil group 2402a and a second coil group 2402b that share a single balun 2404 is provided. The first and second coil groups 2402a, 2402b are formed from a plurality of coil elements 102, a plurality of channels 104, and a plurality of matching circuits 106. Further, the first and second coil groups 2402a, 2402b may, for example, each individually be as in any of the preceding embodiments (e.g., as in the embodiments of FIG. 5).

The plurality of coil elements 102 are arranged in a row extending in the x dimension (e.g., left to right) within the plane of FIG. 24. Further, the plurality of coil elements 102 are grouped into two pairs of neighboring coil elements; one for each of the first and second coil groups 2402a, 2402b. For example, the first coil group 2402a may have the first and second coil elements, and the second coil group 2402b may have the third and fourth coil elements. The plurality of coil elements 102 are illustrated as loop type but one, some, or all of the plurality of coil elements 102 may be saddle type or some other suitable type.

Between each neighboring pair of coil elements is a shared conductive path 108 along which a decoupling capacitor 110 is arranged. Further, the plurality of coil elements 102 have individual conductive paths 112 along which individual capacitors 114 are arranged. However, no capacitors or other reactive elements are on the bottom conductive paths 112b of the middle two coil elements (e.g., the second and third coil elements), so the first and second coil groups 2402a, 2402b share a virtual ground 116. This, in turn, allows the first and second coil groups 2402a, 2402b to share the single balun 2404. This represents a significant reduction in balun count, reducing coil cost and potentially improving coil performance.

With continued reference to FIG. 24, the plurality of channels 104 and the plurality of matching circuits 106 are distributed amongst the first and second coil groups 2402a, 2402b. The first coil group 2402a comprises two matching circuits and two channels, and the second coil group 2402b comprises two matching circuits and two channels. The channels and matching circuits for each multi-element channel structure are as described above (e.g., as described with regard to FIG. 1). For example, within each multi-element channel structure, the matching circuits match each channel to each coil element and include phase shifts and intrinsic impedances to promote isolation between channels.

While a non-shared-shared feed point structure is shown for each multi-element channel structure, a non-shared-non-shared feed point structure is also amenable for one or both of the first and second coil groups 2402a, 2402b. FIG. 1 provides an example of such a structure. Further, the foregoing approach to balun reduction is applicable to two three-loop channels (e.g., each of the coil groups may be individually configured as in FIGS. 21-23) to achieve a 6-channel, one-cable balun configuration.

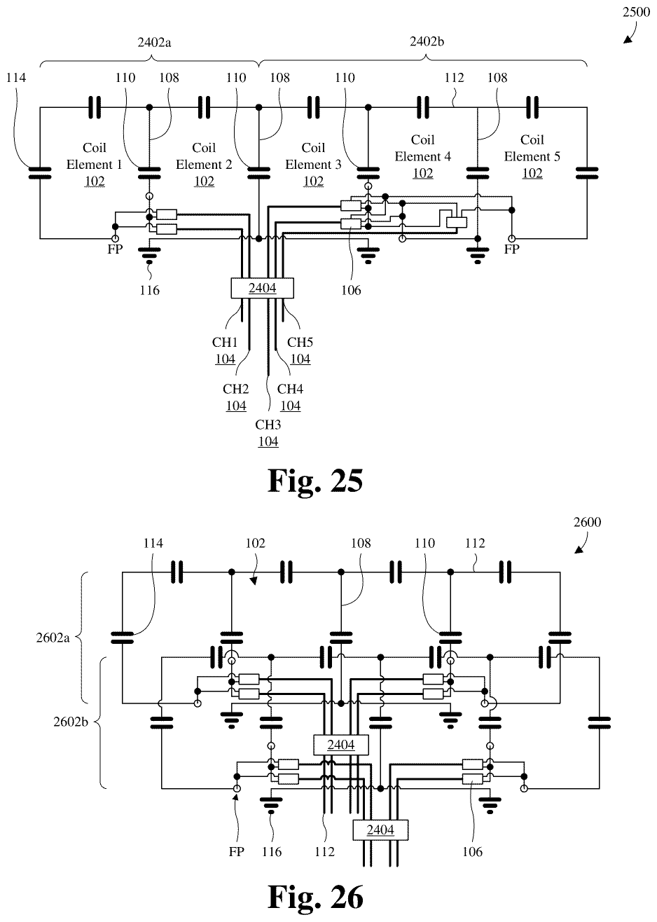

With reference to FIG. 25, a diagram of some alternative embodiments of the MRI RF coil of FIG. 24 is provided in which the first and second coil groups 2402a, 2402b have different total numbers of coil elements. For example, the first coil group 2402a may have two coil elements, whereas the second coil group 2402b may have three coil elements. In alternative embodiments, the shared balun 2404 may be omitted and the first and second coil groups 2402a, 2402b may have individual baluns.

As seen above, the maximum number of channels within a multi-element channel structure equals the number of coil elements within that structure. However, it is to be appreciated that fewer than all available channels may be used depending on different applications. Therefore, the number of channels may be less than the number of coil elements within the multi-element channel structure. Further, so far, the mechanism and benefits of the multi-element channel structure have been discussed. Compared to the traditional phased array coil which uses a single loop or saddle as a building block, the multi-element channel structure may be used as a building block in phased array coils.

With reference to FIG. 26, a diagram 2600 of some embodiments of an MRI RF coil is provided, in which the structure of FIG. 24 is used at a first row 2602a and a second row 2602b that overlap for decoupling. This may, for example, lead to a two-row eight-loop array coil with two cable baluns. While FIG. 26 illustrates the structure of FIG. 24 used for only two rows, more rows are amenable. Further, the MRI RF coil of FIG. 26 and other coils in earlier figures may be used for flat structure coils (e.g., spine coils, torso coils, etc.) and cylindrical or other curved shaped coils (e.g., head coils, knee coils, hand coils, wrist coils, arm coils, leg coils, etc.).

The foregoing discussion has focused on the multi-element channel structure being used in Rx coils. However, the multi-element channel structure may also be used in parallel transmit (pTx) coils. For example, T/R switches may be electrically coupled to the channels in earlier figures (e.g., FIG. 5) to achieve pTx coils.

Note that there is one additional benefit of using the multi-element channel structure to replace a traditional single-element channel structure for pTx applications. The multi-element channel structure has intrinsic improved isolations among channels compared to the traditional single-element channel structure for pTx applications (e.g., a degenerate birdcage structure). Good isolations among pTx channels are important for pTx coil performance.

The reason the multi-element channel structure has improved isolations is that it uses multiple coil elements for each channel. Each coil element only receives partial energy from its driving channel. The isolation between two different channels is the sum of all element pair isolations of the two channels. Since some coil-element pairs of the two channels have excellent isolations and others do not, the summed isolation of the two channels is always better than the worst isolation of any individual coil-element pair, because other coil-element pairs help improve the overall summed isolation.

To better understand this benefit, consider a traditional four-channel pTx coil with a degenerate four-rung birdcage structure. The birdcage structure has a pair of end rings connected by four rungs, which are circumferentially spaced along the end rings. This results in four meshes, each comprising a pair of neighboring rungs connected by portions of the end rings. The meshes correspond to the four channels and are effectively coil elements.

Each mesh of the birdcage coil can be driven independently because of the degenerate configuration. Further, isolations between directly neighboring meshes can be excellent because they can be adjusted by the shared rung capacitors. Therefore, for simplicity, assume directly neighboring meshes have perfect isolation (e.g., isolation values of zero). In contrast to directly neighboring meshes, isolations between non-directly neighboring meshes are not as good. Assume these isolations have an isolation value of a.

Now consider a four-channel pTx coil with a dual-element channel structure according to the present disclosure. Note that FIG. 24 may, for example, be representative of such a coil. The coil has four channels CH1, CH2, CH3, and CH4, where channels CH1 and CH2 correspond to coil elements 1 and 2 and channels CH3 and CH4 correspond to coil elements 3 and 4. Further, all isolations among coil elements are kept the same as those for the four meshes of a traditional four-channel pTx coil so the comparison is fair.

Assume x times channel CH1's energy goes to coil element 1, where the value of x is between 0 and 1. Thus, 1-x times of channel CH1's energy goes to coil element 2. Also assume channel CH1 uses two forward 90-degree phase shifters (e.g., the field pattern of channel CH1 is effectively the sum of field patterns for coil element 1 and coil element 2). What this means is that the field patterns for channel CH2 are effectively the subtraction of field patterns for coil elements 1 and 2. For simplicity, the same assumption is made for channels CH3 and CH4. Then the isolation between channel CH1 and CH3 may be written as in Eq. 3.

$${S}_{{CH}_{1} , {CH}_{3}} = x {S}_{13} x + x {S}_{14} ( 1 - x ) + ( 1 - x ) {S}_{23} x + ( 1 - x ) {S}_{24} ( 1 - x ) = x {S}_{13} x + 0 + 0 + ( 1 - x ) {S}_{24} ( 1 - x ) = {x}^{2} α + {( 1 - x )}^{2} α = ( 1 - 2 x ( 1 - x ) ) α < α \qquad Eq . 3$$

Within Eq. 3, Sᵢⱼ is the isolation between coil element i and coil element j, wherein i and j are integer indexes from 1 to 4. As can be seen, S_{CH1,CH3} is better than α. If x=0.5, S_{CH1,CH3} is 3 dB better than a (e.g., the isolations between non-directly neighboring meshes). Using the same approach of Eq. 3, the value S_{CH1,CH4} is calculated as follows in Eq. 4.

$${S}_{CH 1 , CH 4} = x {S}_{13} x - x {S}_{14} ( 1 - x ) + ( 1 - x ) {S}_{23} x - ( 1 - x ) {S}_{24} ( 1 - x ) = x {S}_{13} x + 0 + 0 - ( 1 - x ) {S}_{24} ( 1 - x ) = {x}^{2} α - {( 1 - x )}^{2} α = ( 2 x - 1 ) α ≪ α \qquad Eq . 4$$

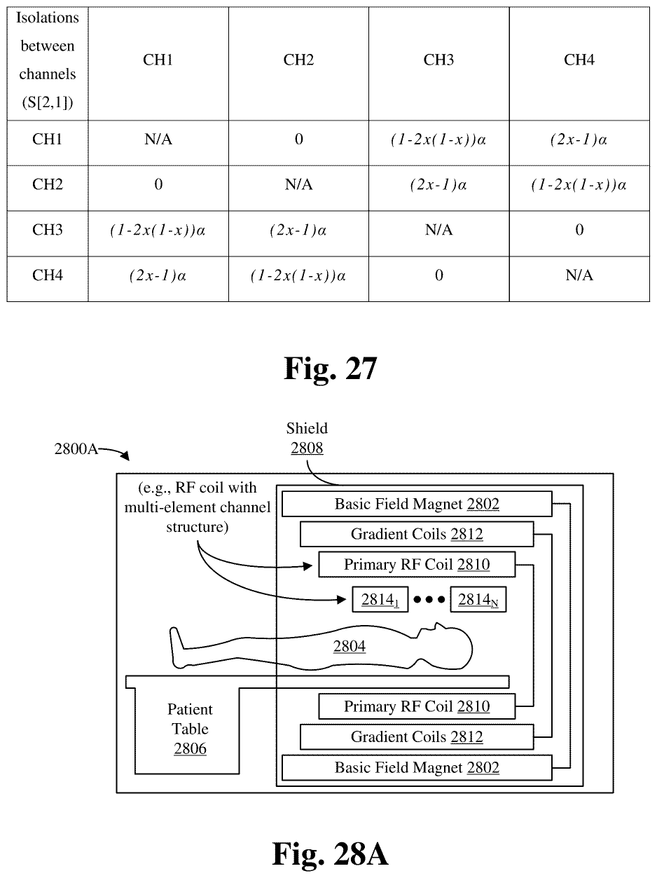

S_{CH1,CH4} is not zero per Eq. 4. However, practically it is almost zero because S_{CH1,CH4} is very small if x is around 0.5. For example, if x=0.5, S_{CH1,CH4} is 0. If x=0.6 or 0.4, S_{CH1,CH4} is 0.2α (e.g., is 7 dB less than a). Based on the foregoing assumptions, S_{CH2,CH3} and S_{CH2,CH4} can also be calculated. The results are in the table of FIG. 27.

With reference to FIG. 27, a table of some embodiments of isolations between channels of the four-channel pTx coil with the dual-element channel structure is provided. As seen, the dual-element channel structure may improve the overall isolations of the pTx coil without changing anything else. The improved isolations may boost performance of pTx applications. Further, the isolation improvements may become even better if more coil elements are used to create one channel (e.g., see FIGS. 21-23) because more coil elements with better isolations may join one channel to compensate for the worst coil element pair isolation. For example, the three-element channel structure may have better overall isolations than the dual-element channel structure.

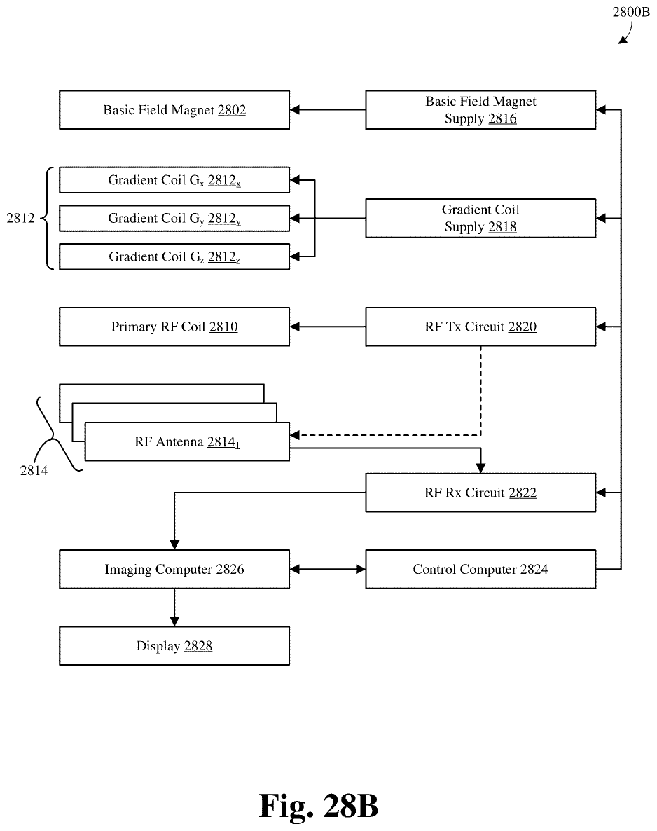

With reference to FIGS. 28A and 28B, various diagrams 2800A, 2800B of some embodiments of an MRI system comprising an RF coil with the multi-element channel structure are provided. FIG. 28A illustrates a high-level diagram 2800A of the MRI system, whereas FIG. 28B illustrates a block diagram 2800B of the MRI system.

Focusing on FIG. 28A, the MRI system uses RF antennas, in the form of coils or coil elements, to transmit and receive RF pulses within a magnetic field (e.g., generated by a basic field magnet 2802). The received pulses are used to create images of tissue of a patient 2804 (e.g., positioned on a patient table 2806) to aid in the diagnosis of medical conditions. Generally, a shield 2808 may substantially contain the generated magnetic fields and RF pulses from the surrounding environment of the MRI system.

In some examples, the MRI system may incorporate a whole-body coil (WBC) (e.g., a primary RF coil 2810, operating in conjunction with gradient coils 2812) as a transmission device. However, the WBC may sometimes be used as a receive device. The WBC is intended for imaging large portions of the body. In lieu of the WBC, a smaller local MRI coil or one or more RF antennas (e.g., one or more local antennas 2814₁, 2814₂, . . . , 2814_{N}) may be employed to receive RF pulses from the anatomy being imaged. In some embodiments, one or more MRI RF coils described with regard to any of FIGS. 1 to 27 may serve as one or more of the primary RF coil 2810 and/or the one or more local antennas 2814₁-2814_{N}.

Focusing on FIG. 28B, the basic field magnet 2802 is electrically coupled to a basic field magnet supply 2816. Ideally, the basic field magnet 2802 produces a uniform or substantially uniform B₀ field. However, in practice, the B₀ field may not be uniform and may vary over an object being imaged by the MRI system.

The gradient coils 2812 are configured to emit gradient magnetic fields, such as Gₓ (e.g., via an associated gradient coil 2812x), G_{y} (e.g., via an associated gradient coil 2812y), and G_{z} (e.g., via an associated gradient coil 2812z). Further, the gradient coils 2812 are electrically coupled to and controlled, at least in part, by a gradient coil supply 2818. In some examples, the timing, strength, and orientation of the gradient magnetic fields may be controlled and thus selectively adapted during an MRI procedure.

The primary RF coil 2810 is configured to generate RF pulses and may, for example, be a WBC or the like. The primary RF coil 2810 is electrically coupled to and controlled, at least in part, by an RF transmission circuit 2820. The RF transmission circuit 2820 may, for example, provide a signal to the primary RF coil 2810.

The one or more local antennas 2814₁, 2814₂, . . . , 2814_{N} (collectively referred to as a set of RF antennas 2814) are configured to generate RF pulses and/or to receive resulting MR signals from an object to which the RF pulses are directed. An RF antenna configured solely to generate RF pulses can be referred to herein as a Tx antenna (or coil), while an RF antenna configured solely to receive resulting MR signals from an object to which the RF pulses are directed can be referred to herein as an Rx antenna (or coil). An RF antenna configured to both generate RF pulses and receive resulting magnetic resonance signals can be referred to herein as a Tx/Rx antenna (or coil). Unless otherwise indicated, antennas, coils, and coil arrays discussed herein can, in various embodiments, be any of a Tx antenna/coil/coil array, an Rx antenna/coil/coil array, or a Tx/Rx antenna/coil/coil array.

One or more members of the set of RF antennas 2814 are or form an MRI RF coil, which has a multi-element channel structure and which may, for example, be as described with regard to any one or combination of FIGS. 1 to 27. The MRI RF coil is electrically coupled to an RF receive circuit 2822 and configured to receive MR signals. Further, the RF receive circuit 2822 may, for example, include a receiver individual to and electrically coupled to each channel of the MRI RF coil. In alternative embodiments, the MRI RF coil is additionally or alternatively electrically coupled to the RF transmission circuit 2820 and is configured to generate RF pulses. The RF transmission circuit 2820 may, for example, include a transmitter individual to and electrically coupled to each channel of the MRI RF coil. To the extent that the MRI RF coil is used for generating RF pulses, the MRI RF coil may be used in a pTx mode or some other suitable mode.

The gradient coils supply 2818 and the RF transmission circuit 2820 are controlled, at least in part, by a control computer 2824. The MR signals received from the set of RF antennas 2814 may be employed to generate an image. Hence, the MR signals may be subject to a transformation process, such as a two-dimensional (2D) fast Fourier transform (FFT) that generates pixelated image data. The transformation may be performed by an image computer 2826 or other similar processing device. The image data may, for example, be shown on a display 2828. The RF receive circuit 2822 may, for example, be electrically coupled to the control computer 2824 or the image computer 2826.

While FIGS. 28A and 28B illustrate an example MRI system that includes various components connected in various ways, it is to be appreciated that other MRI systems can include other components connected in other ways and can be employed in connection with various embodiments discussed herein.

With reference to FIG. 2900, a diagram 2900 of some alternative embodiments of the MRI system according to FIGS. 28A and 28B is provided in which the MRI system further comprises a T/R switch circuit 2902.

The T/R switch circuit 2902 is configured to electrically couple the MRI RF coil formed by the set of RF antennas 2814 selectively to the RF transmission circuit 2820 and the RF receive circuit 2822. For example, in a receive mode, the T/R switching circuit 2902 may be controlled to electrically couple the MRI RF coil to the RF receive circuit 2822. Further, in a transmit mode, the T/R switching circuit 2902 may be controlled to electrically couple the MRI RF coil to the RF transmission circuit 2820. Such control may, for example, be by the control computer 2824 or some other suitable device. The T/R switch circuit 2902 may, for example, include a T/R switch individual to and electrically coupled to each channel of the MRI RF coil. Further, as noted above, the MRI RF coil has a multi-element channel structure and may, for example, be as described with regard to any one or combination of FIGS. 1 to 27.

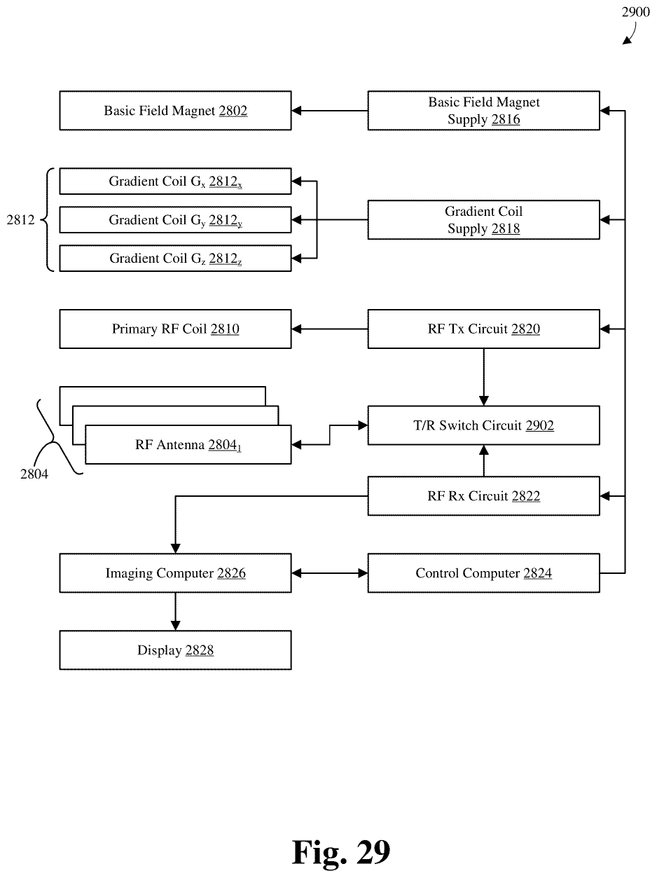

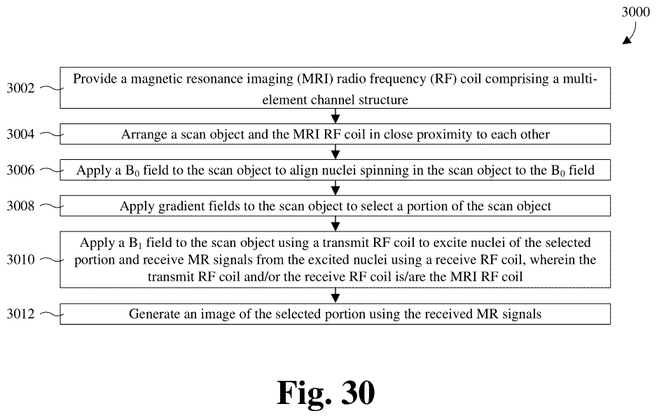

With reference to FIG. 30, a block diagram 3000 of some embodiments of a method of performing MRI using an MRI RF coil comprising a multi-element channel structure is provided. The method may, for example, be employed using the MRI system in FIGS. 28A and 28B, the MRI system in FIG. 29, or some other suitable MRI system.

At act 3002, an MRI RF coil comprising a multi-element channel structure is provided. The MRI RF coil may, for example, be as described with regard to any one or combination of FIGS. 1 to 27.

At act 3004, a scan object and the MRI RF coil are arranged in close proximity to each other.

At act 3006, a B₀ field is applied to the scan object to align nuclei spinning in the scan object to the B₀ field.

At act 3008, gradient fields are applied to the scan object to select a portion of the scan object.

At act 3010, a B₁ field is applied to the scan object using a transmit RF coil to excite nuclei of the selected portion. Further, MR signals are received from the excited nuclei using a receive RF coil. The transmit RF coil and/or the receive RF coil is/are the MRI RF coil.

At acts 3012, an image of the selected portion is generated using the received MR signals.

Collectively, acts 3004 to 3012 may be regarded as the act of performing MRI on the scan object to generate the image of the scan object using the MRI RF coil as the transmit RF coil and/or as the receive RF coil.

While the block diagram 3000 of FIG. 30 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts may be required to implement one or more aspects or embodiments of the description herein, and one or more of the acts depicted herein may be carried out in one or more separate acts and/or phases.

In view of the foregoing, some embodiments of the present disclosure provide an MRI RF coil, including: a first channel port and a second channel port; a first coil element and a second coil element that border each other; a first matching circuit electrically coupled from the first channel port to the first coil element and to the second coil element; and a second matching circuit electrically coupled from the second channel port to the first coil element and to the second coil element; where each of the first and second matching circuits is configured to match the first and second coil elements simultaneously. In some embodiments, the first matching circuit is configured to deliver a first current and a second current respectively to the first and second coil elements, where the second matching circuit is configured to deliver a third current and a fourth current respectively to the first and second coil elements, and where a dot product of a first current vector, including the first and second currents, with a second current vector, including the third and fourth currents, is about zero. In some embodiments, the MRI RF coil further includes a decoupling capacitor between and shared by the first and second coil elements. In some embodiments, the first and second coil elements are respectively a loop coil element and a saddle coil element. In some embodiments, the first and second coil elements are both loop coil elements or both saddle coil elements. In some embodiments, the MRI RF coil further includes: a third channel port; a third coil element; and a third matching circuit electrically coupled from the third channel port to the first coil element, to the second coil element, and to the third coil element. In some embodiments, the first matching circuit includes a first lattice balun and a second lattice balun electrically coupled from the first channel port respectively to a feed point of the first coil element and a feed point of the second coil element, where the second matching circuit includes a third lattice balun and a fourth lattice balun electrically coupled from the second channel port respectively to the feed point of the first coil element and the feed point of the second coil element. In some embodiments, the first, second, and third lattice baluns are configured to provide +90° phase shifts, where the fourth lattice balun is configured to provide a −90° phase shift. In some embodiments, the first matching circuit includes a first quarter wavelength transformer and a second quarter wavelength transformer electrically coupled from the first channel port respectively to the first and second coil elements. In some embodiments, the first and second quarter wavelength transformers are of different types. In some embodiments, the first quarter wavelength transformer includes a low-pass or high-pass phase shifter. In some embodiments, the first quarter wavelength transformer includes a “T” or “π” phase shifter. In some embodiments, the MRI RF coil further includes: a first coil channel group including the first and second channel ports, the first and second coil elements, and the first and second matching circuits; and a second coil channel group having a total number of coil elements different than a total number of coil elements in the first coil channel group.

Further, additional embodiments of the present disclosure provide an MRI system, including: an MRI RF coil, including: a first channel group, including: a first channel port and a second channel port; a first coil element and a second coil element that border each other; a first matching circuit electrically coupled from the first channel port to the first coil element and to the second coil element; and a second matching circuit electrically coupled from the second channel port to the first coil element and to the second coil element; and a second channel group including a third channel port, a fourth channel port, a third coil element, and a fourth coil element; an RF circuit; and a plurality of cables individual to and electrically coupled from the RF circuit respectively to the first, second, third, and fourth channel ports. In some embodiments, the first and second channel groups are in different rows of the MRI RF coil and the first channel group overlaps with and is spaced from the second channel group. In some embodiments, the MRI system further includes a single cable balun along the plurality of cables, where the first, second, third, and fourth coil elements are in a common row with the second and third coil elements sharing a rung that serves as a virtual ground. In some embodiments, the RF circuit corresponds to a transmit/receive switch. In some embodiments, the first matching circuit includes a first phase shifter and a second phase shifter electrically coupled from the first channel port respectively to a feed point of the first coil element and a feed point of the second coil element, where the second matching circuit includes a third phase shifter and a fourth phase shifter electrically coupled from the second channel port respectively to the feed point of the first coil element and the feed point of the second coil element.

Further, additional embodiments of the present disclosure provide a method, including: providing an RF coil that includes a first channel port, a second channel port, a first coil element, a second coil element, a first matching circuit electrically coupled from the first channel port to the first coil element and to the second coil element, and a second matching circuit electrically coupled from the second channel port to the first coil element and to the second coil element; and performing MRI on a scan object to generate an image of the scan object using the RF coil as a transmit coil and/or as a receive coil; where, during MRI, the first matching circuit results in a current a in the first coil element and a current b in the second coil element, the second matching circuit results in a current c in the first coil element and a current d in the second coil element, and ac+bd=0 to electrically isolate the first and second channel ports. In some embodiments, the performing of MRI includes generating a B₀ magnetic field, where the first and second coil elements share a conductive rung that extends perpendicular to the B₀ magnetic field and that accommodates a decoupling capacitor.

The following includes definitions of selected terms employed herein. The definitions include various examples or forms of components that fall within the scope of a term and that may be used for implementation. The examples are not intended to be limiting. Both singular and plural forms of terms may be within the definitions.

The terminology used herein is for the purpose of describing particular embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which embodiments belong. It will be further understood that terms (e.g., those defined in commonly used dictionaries) should be interpreted as having a meaning that is consistent with their meaning in the context of the relevant art and will not be interpreted in an idealized or overly formal sense unless expressly so defined herein.

In the above description, some components may be displayed in multiple figures carrying the same reference signs and/or names but may not be described multiple times in detail. A detailed description of a component may then apply to that component for all its occurrences. Further, numerical designations (e.g., first, second, third, etc.) may be used for clarity to distinguish between components of the same type. However, it is to be appreciated that the numerical designation may vary for components displayed in multiple figures, depending upon context. For example, a component referred to as third in one figure may be referred to as fourth in another figure if another component of the same type already has the designation of third.

The detailed descriptions presented herein may be presented in terms of algorithms and symbolic representations of operations on data bits within a memory. These algorithmic descriptions and representations are used by those skilled in the art to convey the substance of their work to others. An algorithm, here and generally, is conceived to be a sequence of operations that produce a result. The operations may include physical manipulations of physical quantities. Usually, though not necessarily, the physical quantities take the form of electrical or magnetic signals capable of being stored, transferred, combined, compared, manipulated in a logic, and so on. The physical manipulations create a concrete, tangible, useful, real-world result.

It has proven convenient at times, principally for reasons of common usage, to refer to these signals as bits, values, elements, symbols, characters, terms, numbers, and so on. It should be borne in mind, however, that these and similar terms are to be associated with the appropriate physical quantities and are merely convenient labels applied to these quantities. Unless specifically stated otherwise, it is appreciated that throughout the description, terms including processing, computing, calculating, determining, and so on refer to actions and processes of a computer system, logic, processor, or similar electronic device that manipulates and transforms data represented as physical and/or electronic quantities.

Example methods may be better appreciated with reference to flow diagrams. While for purposes of simplicity of explanation, the illustrated methodologies are shown and described as a series of blocks, it is to be appreciated that the methodologies are not limited by the order of the blocks, as some blocks can occur in different orders and/or concurrently with other blocks from that shown and described. Moreover, less than all the illustrated blocks may be required to implement an example methodology. Blocks may be combined or separated into multiple components. Furthermore, additional and/or alternative methodologies can employ additional, not illustrated blocks.

What is claimed is:

1. A magnetic resonance imaging (MRI) radio frequency (RF) coil, comprising:
a first channel port and a second channel port;
a first coil element and a second coil element that border each other;
a first matching circuit electrically coupled from the first channel port to the first coil element and to the second coil element; and
a second matching circuit electrically coupled from the second channel port to the first coil element and to the second coil element;
wherein each of the first and second matching circuits is configured to match the first and second coil elements simultaneously.

2. The MRI RF coil according to claim 1, wherein the first matching circuit is configured to deliver a first current and a second current respectively to the first and second coil elements, wherein the second matching circuit is configured to deliver a third current and a fourth current respectively to the first and second coil elements, and wherein a dot product of a first current vector, comprising the first and second currents, with a second current vector, comprising the third and fourth currents, is about zero.

3. The MRI RF coil according to claim 1, further comprising:
a decoupling capacitor between and shared by the first and second coil elements.

4. The MRI RF coil according to claim 1, wherein the first and second coil elements are respectively a loop coil element and a saddle coil element.

5. The MRI RF coil according to claim 1, wherein the first and second coil elements are both loop coil elements or both saddle coil elements.

6. The MRI RF coil according to claim 1, further comprising:
a third channel port;
a third coil element; and
a third matching circuit electrically coupled from the third channel port to the first coil element, to the second coil element, and to the third coil element.

7. The MRI RF coil according to claim 1, wherein the first matching circuit comprises a first lattice balun and a second lattice balun electrically coupled from the first channel port respectively to a feed point of the first coil element and a feed point of the second coil element, and wherein the second matching circuit comprises a third lattice balun and a fourth lattice balun electrically coupled from the second channel port respectively to the feed point of the first coil element and the feed point of the second coil element.

8. The MRI RF coil according to claim 7, wherein the first, second, and third lattice baluns are configured to provide +90° phase shifts, and wherein the fourth lattice balun is configured to provide a −90° phase shift.

9. The MRI RF coil according to claim 1, wherein the first matching circuit comprises a first quarter wavelength transformer and a second quarter wavelength transformer electrically coupled from the first channel port respectively to the first and second coil elements.

10. The MRI RF coil according to claim 9, wherein the first and second quarter wavelength transformers are of different types.

11. The MRI RF coil according to claim 9, wherein the first quarter wavelength transformer comprises a low-pass or high-pass phase shifter.

12. The MRI RF coil according to claim 9, wherein the first quarter wavelength transformer comprises a “T” or “π” phase shifter.

13. The MRI RF coil according to claim 1, wherein the MRI RF coil further comprises:
a first coil channel group comprising the first and second channel ports, the first and second coil elements, and the first and second matching circuits; and
a second coil channel group having a total number of coil elements different than a total number of coil elements in the first coil channel group.

14. A magnetic resonance imaging (MRI) system, comprising:
an MRI radio frequency (RF) coil, comprising:
a first channel group, comprising:
a first channel port and a second channel port;
a first coil element and a second coil element that border each other;
a first matching circuit electrically coupled from the first channel port to the first coil element and to the second coil element; and
a second matching circuit electrically coupled from the second channel port to the first coil element and to the second coil element; and
a second channel group comprising a third channel port, a fourth channel port, a third coil element, and a fourth coil element;
an RF circuit; and
a plurality of cables individual to and electrically coupled from the RF circuit respectively to the first, second, third, and fourth channel ports.

15. The MRI system according to claim 14, wherein the first and second channel groups are in different rows of the MRI RF coil and the first channel group overlaps with and is spaced from the second channel group.

16. The MRI system according to claim 14, further comprising:
a single cable balun along the plurality of cables, wherein the first, second, third, and fourth coil elements are in a common row with the second and third coil elements sharing a rung that serves as a virtual ground.

17. The MRI system according to claim 14, wherein the RF circuit corresponds to a transmit/receive switch.

18. The MRI system according to claim 14, wherein the first matching circuit comprises a first phase shifter and a second phase shifter electrically coupled from the first channel port respectively to a feed point of the first coil element and a feed point of the second coil element, and wherein the second matching circuit comprises a third phase shifter and a fourth phase shifter electrically coupled from the second channel port respectively to the feed point of the first coil element and the feed point of the second coil element.

19. A method, comprising:
providing a radio frequency (RF) coil that comprises a first channel port, a second channel port, a first coil element, a second coil element, a first matching circuit electrically coupled from the first channel port to the first coil element and to the second coil element, and a second matching circuit electrically coupled from the second channel port to the first coil element and to the second coil element; and
performing magnetic resonant imaging (MRI) on a scan object to generate an image of the scan object using the RF coil as a transmit coil and/or as a receive coil;
wherein, during MRI, the first matching circuit results in a current a in the first coil element and a current b in the second coil element, the second matching circuit results in a current c in the first coil element and a current d in the second coil element, and ac+bd=0 to electrically isolate the first and second channel ports.

20. The method according to claim 19, wherein the performing of MRI comprises:
generating a B₀ magnetic field, wherein the first and second coil elements share a conductive rung that extends perpendicular to the B₀ magnetic field and that accommodates a decoupling capacitor.
